(19) United States
(12) Patent Application Publication
(10) Pub. No.: US 2023/0266373 A1
(43) Pub. Date: Aug. 24, 2023

(54) METHOD, MEASURING STATION AND SYSTEM FOR DETERMINING THE BEHAVIOUR OF ONE ELECTRICAL OR ELECTRONIC POWER COMPONENT

(71) Applicant: IPERA S.R.L., Salerno (IT)

(72) Inventors: Nicola Femia, Salerno (IT); Giulia Di Capua, Salerno (IT)

(21) Appl. No.: 18/002,618

(22) PCT Filed: Nov. 5, 2021
(86) PCT No.: PCT/IB2021/060270

§ 371 Date: Dec. 20, 2022

(30) Foreign Application Priority Data
Nov. 6, 2020 (IT) 102020000026599

(51) Int. Cl. G01R 27/26; G01R 31/40; G01R 31/72

(52) U.S. Cl. CPC G01R 27/2611; G01R 31/40; G01R 31/72

(57) ABSTRACT

Method for determining the behaviour of one electrical or electronic power component (2), with respect to a working limit condition, the method comprising the following operational steps: A. defining one three-dimensional mathematical space (3) of operational parameters of interest for the electrical or electronic power component (2), wherein the coordinates of an n-th point Pₙ of the three-dimensional mathematical space (3) correspond to specific values of the operational parameters of interest for the electrical or electronic power component (2); B. defining one exploration field (4) of the three-dimensional mathematical space, one working limit condition for the electrical or electronic power component (2) and one set R of response parameters of interest for the electrical or electronic power component (2); C. exploring, said three-dimensional mathematical space (3) by: - the generation of at least one stimulus, determined based on the coordinates of the points Pₙ of the three-dimensional mathematical space (3) and based on the exploration field (4), - the application of the at least one stimulus, to the at least one electrical or electronic power component (2), and - the detection of one corresponding response to the stimulus thereby applied, from the electrical or electronic power component (2), and based on the response thereby detected, determining, and storing one finite subset of points P^{∗}ₙ of said mathematical space (3) among the points Pₙ of the mathematical space (3), for which that working limit condition of that electronic power component (2) is met; and D. determining one mathematical model that analytically describes the locus of the points P^{∗}ₙ of that three-dimensional mathematical space (3) thereby stored, thereby obtaining the locus (5) of the operational parameters that determine a response from said electrical or electronic power component (2) that meets that working limit condition.

The present invention relates to a method for determining the behaviour of an electrical or electronic power component, more particularly of an inductor, operating under typical operating conditions of power generators, wherein that inductor is used as an energy periodic temporary storage element, to carry out a static energy conversion process.

The present invention also relates to a measuring station and a system configured to implement such a method.

Before going into the merits of the present invention it is noted that explicit reference will be made hereinafter to an inductor as an element of periodic temporary storage of energy. However, it must be kept in mind that the present invention can be applied in a completely analogous way also to capacitors as will become clear in the following.

The operating conditions of an inductor which are of particular interest for the present invention are those imposed by a periodic charge-discharge process. In said process, a zero mean square wave time-varying voltage v_{L}(t) is applied to the inductor terminals, for example by means of active and passive semiconductor devices, which operate as electronic switches that alternately connect the terminals of the inductor to electronic components configured to impose a positive or negative voltage value, thus obtaining in a first step, an energy transfer from an energy source towards the inductor and, in the second step, an energy transfer from the inductor to a load.

The electrical behaviour of the inductor, resulting from this periodic charge-discharge process, can be determined based on the trend of the current i_{L}(t) flowing therethrough, which current varies over time. The current flowing through such an inductor during the periodic charge-discharge process is comparable to a periodic triangular wave, with a positive slope in the charging step of the inductor and a negative slope in the discharge step of the inductor. The triangular wave of the current flowing through the inductor can be subjected to more or less accentuated slope variations, in each of the two steps (charge and/or discharge), due to the more or less abrupt occurrence of the saturation phenomenon of the inductor electronic core, as the variable current flowing therethrough varies.

As a rule, the behaviour of a commercially available inductor is experimentally determined by its manufacturer, using different types of techniques, with the aim of quantifying one of its characteristic parameters, specifically the self-inductance coefficient L. The self-inductance coefficient is usually represented in graphical form as a function of the variable average current flowing through the inductor and parametrized as a function of the environmental temperature.

Traditionally, a manufacturer of a commercially available inductor also obtains, from the results of experimental tests that he performs on the component, useful information for the formulation of heuristic loss equations (for example through Steinmetz formulas), depending on the conditions in which such component can operate, for example when the frequency varies.

Over time, techniques and apparatuses have been developed for determining the behaviour of inductors, in relation to the varying conditions in which they operate.

These determination techniques with their respective apparatuses, however, suffer from many drawbacks. For example, in some cases they are not informative, as they provide parameters that do not assume unique values, as they are subject to variations according to the operational parameters of the components. In particular, reference is made to the inductor’s self-induction coefficient L, expressed at most as a function of the average current flowing therethrough and the environmental temperature. The self-induction coefficient L is traditionally provided as it is usually used to calculate the performance of inductors, such as peak-to-peak current ripple and losses, although, in fact, it does not assume a unique value as it varies according to, for example, the working frequency, the voltage and the duty-cycle, as well as the current and the temperature.

Grids of parameter values are also traditionally used to generate signals to be sent to the inductors during the execution of experimental tests thereon. Those grids cover multidimensional domains, the exploration of which is carried out through nested scanning cycles of each quantity, which nested scanning cycles may include — if not appropriately restricted — n-tuple of operational quantities corresponding to unsustainable operational conditions of the inductor being evaluated and, therefore, such that they compromise the test results due to inductor failures that may occur and the consequent possible damage to the hardware used for the test. This type of approach is also very demanding from a computational point of view.

The determination of the behaviour of the inductors is also traditionally performed by carrying out tests on these components in small-signal sinusoidal regime, which tests however do not reflect the real working conditions of the inductors in power generators.

Complex architectures of test systems are also adopted to determine the behaviour of these inductors, which architectures require a programmable electronic load for the imposition of the desired current on the inductor under test and for the automation of the test cycles.

Some examples of the above traditional apparatuses and methods are, for example, taught in EP2807589B1, US7307412B1 and US20120316817A1. Further traditional methods for determining a characteristic parameter of a device are described in US 5793640 and in US 2016/0132625.

In any case, all the methods traditionally used provide information that does not express in a direct and easy to understand way, the relationship between the operational conditions to which an inductor is normally subjected (for example, the frequency of oscillation of the voltage, average current and the environmental temperature) and its response parameters such as, for example, current ripple, dissipated power and surface temperature.

The need is therefore felt to improve the state of the art in the field of electrical or electronic power components and, thus, the main object of the present invention is to provide a method for determining the behaviour of an electrical or electronic power component which is safe, in the sense that its implementation does not cause faults in the electrical or electronic power component under test or in the used hardware, that is less demanding from a computational point of view, that is reliable and provides for more easily interpretable and useful results for the purpose, compared to traditional methods.

A further object of the present invention is to provide for a measuring station, configured for the implementation of the aforementioned method.

Not the least object of the present invention is to provide a system for the implementation of the method for determining the behaviour of an electrical or electronic power component, which is easy to implement and use.

It is a specific object of the present invention a method for determining the behaviour of one electrical or electronic power component, with respect to a working limit condition, the method comprising the following operational steps:
A. defining one three-dimensional mathematical space of operational parameters of interest for said electrical or electronic power component, wherein the coordinates of an n-th point Pₙ of said three-dimensional mathematical space correspond to specific values of said operational parameters of interest for said electrical or electronic power component;
B. defining one field of exploration of said three-dimensional mathematical space, one working limit condition for said electrical or electronic power component and one set R of response parameters of interest for said electrical or electronic power component;
C. exploring, said three-dimensional mathematical space by:
   generating at least one stimulus, determined based on the coordinates of the points Pₙ of said three-dimensional mathematical space and on said field of exploration,
   applying said at least one stimulus, to said at least one electrical or electronic power component, and
   detecting one corresponding response to said stimulus thereby applied, from said electrical or electronic power component, and
      based on said response thereby detected, determining, and storing one finite subset of points P*ₙ of said three-dimensional mathematical space among the points Pₙ of said three-dimensional mathematical space, for which said working limit condition of said electronic power component is met; and
D. determining one mathematical model that analytically describes the locus of said points P*ₙ of said three-dimensional mathematical space thereby stored, thereby obtaining the locus of said operational parameters that determine a response of said electrical or electronic power component hat meets said working limit condition.

According to another aspect of the invention, said operational parameters of interest for said electrical or electronic power component can be selected among:
one equivalent voltage to be applied to said electrical or electronic power component;
one switching frequency for one entire charge-discharge cycle of said electrical or electronic power component;
one average current flowing thorough said electrical or electronic power component; and
one temperature of the environment wherein said electrical or electronic power component is operational.

According to a further aspect of the invention, said three-dimensional mathematical space can be defined by assigning to each one of said operational parameters of interest of said electrical or electronic power component, one corresponding mathematical axis of an Euclidean three-dimensional mathematical space.

According to an additional aspect of the invention, said field of exploration can be defined by selecting:
one finite subset of points Pₙ of said three-dimensional mathematical space; and
one ordered set of three directions of exploration of the points of said field of exploration, from any point Pₙ₋₁ to a next point Pₙ, each direction of exploration being optionally parallel to a respective axis of said three-dimensional mathematical space.

According to another aspect of the invention, the exploration of said three-dimensional mathematical space can be carried out, starting from one starting point Pₙ of said field of exploration, along said directions of exploration, in an orderly way, and according to one exploration rule such that the coordinates of an explored n-th point Pₙ of said three-dimensional mathematical space differ from those of a previous point Pₙ₋₁, for the value of one or more of its components.

According to a further aspect of the invention, the coordinates of said points Pₙ of said field of exploration can have values comprised between one minimum value and one maximum value of respective operational parameters and the finite number of said points Pₙ of said field of exploration can be a function, for each one of said directions of exploration of said three-dimensional mathematical space, of
one number of samples; and
one offset between one sample and the next one along the respective direction of exploration.

According to an additional aspect of the invention, for each direction of said directions for exploration:
said number of samples can be fixed, and said offset can be fixed and constant; or
said number of samples can be fixed, and said offset can vary between two subsequent samples, optionally according to one function selectable between a pre-set logarithmic, power, trigonometric, transcendent, or numerical series function; or
said number of samples can depend on one offset that is calculated, during said exploration of said exploration field (4), for each point Pₙ, optionally based on one value of one set R of response parameters, which response parameters are calculated at the two points Pₙ₋₁ e Pₙ₋₂ that were last explored in said field of exploration.

According to another aspect of the invention, the compliance or not of said working limit condition in any point Pₙ of said three-dimensional mathematical space can depend on the value of at least one response parameter of said set R of response parameters of said electrical or electronic power component, the response parameters being determined based on the response detected from said electrical or electronic power component, after the application of said stimulus to its terminals, and on a pre-set search logic.

According to a further aspect of the invention, said response parameter of said set R of response parameters of said electrical or electronic power component can be one among:
one peak-to-peak variation of a current that varies with time and flows through said electrical or electronic power component;
one surface temperature of said electrical or electronic power component;
one average electrical power dissipated by said electrical or electronic power component.

According to an additional aspect of the invention, said working limit condition of said electrical or electronic power component can be a function of a prefixed threshold value for each response parameter.

According to another aspect of the invention, said at least one response parameter can be compliant with said at least one working limit condition if its value is lower than or equal to a respective threshold value.

According to another aspect of the invention, said step C can comprise:
C.1 selecting, through a data control and processing unit, one starting point Pₙ comprised in said exploration field (4) and one first direction of exploration of said field of exploration;
C.2 generating, through one stimulus generating device, one stimulus comprising one varying over time voltage and one constant average current, based on the value of the coordinates of said point Pₙ just selected, and applying said stimulus thereby generated to the terminals of said electrical or electronic power component;
C.3 detecting at the terminals of said electrical or electronic power component, through one detecting device, in reply to said stimulus thereby applied, at least one corresponding current which varies over time, flowing through said electrical or electronic power component, and one corresponding surface temperature;
C.4 determine, through said data control and processing unit, said set R of response parameters, based on said current and said surface temperature thereby detected; and
C.5 compare, through said data control and processing unit, each element of said set R of response parameters with said working limit condition; and
C.6 if said working limit condition is met in said point Pₙ:
   C.6.1 selecting a new point Pₙ of said three-dimensional mathematical space, along said first selected direction of exploration; and
   C.6.2 if said point Pₙ is comprised within said field of exploration, going back to step C.2; otherwise going to step C.8
C.7 if said working limit condition is not met in said point Pₙ:
   C.7.1if said point Pₙ just selected is the starting point of said field of exploration:
      C.7.1.1 selecting a new point Pₙ of said three-dimensional mathematical space, along said first selected direction of exploration; and
      C.7.1.2 if said new point Pₙ is comprised within said field of exploration:
         C.7.1.2.1 carrying out steps C.2-C.5 and
         C.7.1.2.2 if said working limit condition is not met for said new point Pₙ, going back to step C.7.1.1,
         otherwise going to step C.6;
      otherwise going to step C.8
      otherwise
   C.7.2 if said point Pₙ just selected and the point Pₙ₋₁ previous to that are placed along said first direction of exploration:
      C.7.2.1 determining, through said data control and processing unit, and storing, in a storage unit, the coordinates of another point P*ₙ of the three-dimensional space 3, that is comprised in the neighbourhood of said point Pₙ of said field of exploration, along said first selected direction of exploration, wherein said working limit condition is met;
      C.7.2.2 selecting the point Pₙ₋₁ previous to said Pₙ and, starting from that, a new point Pₙ, along the second direction of exploration; and
      C.7.2.3 if said newly selected point Pₙ is comprised within said field of exploration, going back to step C.2;
      otherwise going to step C.8
      otherwise
   C.7.3 if said point Pₙ just selected and the point Pₙ₋₁ previous to that are placed along the second direction of exploration:
      C.7.3.1 selecting a new point Pₙ of the three-dimensional mathematical space, along the first selected direction of exploration; and
      C.7.3.2 if said newly selected point Pₙ is comprised within said field of exploration, going back to step C.2;
      otherwise going to step C.8
C.8 if said point Pₙ just selected is not comprised within said field of exploration:
   C.8.1 selecting, along said second direction of exploration, a new point Pₙ of the three-dimensional mathematical space, starting from the previously selected point Pₙ₋₁ and, if the newly selected point Pₙ is comprised within said field of exploration, going back to step C.2; otherwise
   C.8.2 selecting, along said third direction of exploration, a new point Pₙ of the three-dimensional mathematical space, starting from the previously selected point Pₙ₋₁ and, if the newly selected point Pₙ is comprised within said field of exploration, going back to step C.2; otherwise going to said step D of said method.

According to an additional aspect of the invention, the stored coordinates of said point P*ₙ of said mathematical space, which point is comprised in the neighbourhood of said point Pₙ of said field of exploration, can be calculated through an interpolation formula, optionally a linear one.

According to another aspect of the invention, said step D can comprises applying to said points thereby stored, through said data control and processing unit, at least one Genetic Programming or Grammatical Evolution algorithm.

It is further a specific object of the invention, a measuring station, configured for implementing the method for determining the behaviour of an electrical or electronic power component as described above, comprising:
one data control and processing unit, configured for defining said three-dimensional mathematical space, said field of exploration, said working limit condition, said set R of response parameters, and configured for comparing said set R with said working limit condition;
one stimulus generating device, operatively connected to said data control and processing unit and configured for generating at least one stimulus, the stimulus comprising at least one zero mean and square wave voltage and one constant average current for said electrical or electronic power component, based on the value of the coordinates of said point Pₙ of said three-dimensional mathematical space, said coordinates being associated to respective values of said operational parameters of said electrical or electronic power component, and for applying said stimulus thereby generated to said electrical or electronic power component;
one detecting device, operatively connected to said data control and processing unit and configured for detecting said at least one varying over time current and one surface temperature of said electrical or electronic power component, in reply to said stimulus thereby applied;
at least one storage unit, operatively connected to said data control and processing unit and configured for storing the coordinates of the points P*ₙ of said mathematical space wherein said working limit condition is met;
wherein said data control and processing unit is configured for applying to said coordinates of said points P*ₙ thereby stored, at least one mathematical algorithm, optionally a Genetic Programming or Grammatical Evolution algorithm, said at least one mathematical algorithm providing for in output a description, in analytical form, of the locus of said points P*ₙ, and therefore the locus of the corresponding operational parameters that determine a response from said electrical or electronic power component that meets said at least one working limit condition.

According to another aspect of the invention, said one stimulus generating device and said detecting device can be obtained through three power converter stages operatively connected in cascade according to an Opposition Method, so as to:
subject said at least one electrical or electronic power component to said at least one stimulus, based on the value of the coordinates of said point Pₙ; and
detect at least one varying over time current and one surface temperature Tₛ of said electrical or electronic power component.

According to a further aspect of the invention, said three power converter stages can comprise an Input Stage, a Test Stage, and an Output Stage, wherein the Test Stage is connected between the Input Stage and the Output stage and is further configured to be connected to said electrical or electronic power component.

According to an additional aspect of the invention, said measuring station can comprise downstream of said Output Stage one switching element for the current output from said Output Stage, toward the input of the Test Stage or an external load.

According to a further aspect of the invention, said Input Stage can be configured to work in closed loop and provide in input to said Test Stage one direct voltage, through the adjustment of the output voltage thereof, and said Test stage is configured to work in open loop and provide for a switching frequency of said zero mean and square wave voltage, through the adjustment of its own frequency and duty cycle.

According to another aspect of the invention, said Output stage can be configured to operate in closed loop and impose at the output of said Test Stage a direct current, through the adjustment of its own input average current.

According to an additional aspect of the invention, said measuring station can comprise:
one printed circuit having conductive paths, configured for imposing said stimulus to said electrical or electronic power component, wherein said conductive paths have at least one surface portion configured for electrically entering into contact with said electrical or electronic power component; and
one positioning system for said electrical or electronic power component on said printed circuit, wherein said electrical or electronic power component is in electrical contact with said conductive paths of said printed circuit, without need for welds.

According to a further aspect of the invention, said positioning system can comprise:
one positioning plate; and
one group for the elastic anchoring of said positioning plate to said printed circuit;
said electrical or electronic power component being configured for being placed between said printed circuit and said positioning plate and being subjected to one pressure toward said conductive paths of said printed circuit, through said elastic anchoring group.

According to a further aspect of the invention, said elastic anchoring group can comprise one couple of elastically charged screws, configured for being screwed on said printed circuit, passing through suitable openings obtained in said positioning plates.

According to an additional aspect of the invention, said conductive paths can have a polygonal configuration, optionally a trapezoidal configuration.

According to another aspect of the invention, said detecting device can comprise at least one temperature sensor, operatively connected to said data control and processing unit, and configured for detecting said surface temperature of said electrical or electronic power component and for transmitting it to said data control and processing unit.

It is also a specific object of the invention a system for implementing the method for determining the behaviour of an electrical or electronic power component as described above, comprising at least one measuring station as described above and at least one remote processing unit, wherein said measuring station and said remote processing unit are operatively connected to each other, optionally through one network, optionally through one cable or wirelessly, and wherein said data control and processing unit of said measuring station is configured to send to said at least one remote processing unit said coordinates of said points P*ₙ thereby stored, and said at least one remote processing unit is configured to apply at least one mathematical algorithm, optionally a Genetic Programming or Grammatical Evolution algorithm, providing for in output a description, in analytical form, of the locus of said points P*ₙ, and therefore the locus of the corresponding operational parameters that determine a response from said electrical or electronic power component that meets at least one working limit condition.

The present invention will be now described, for illustrative but not limiting purposes, according to its preferred embodiments, with particular reference to the Figures of the accompanying drawings, wherein:

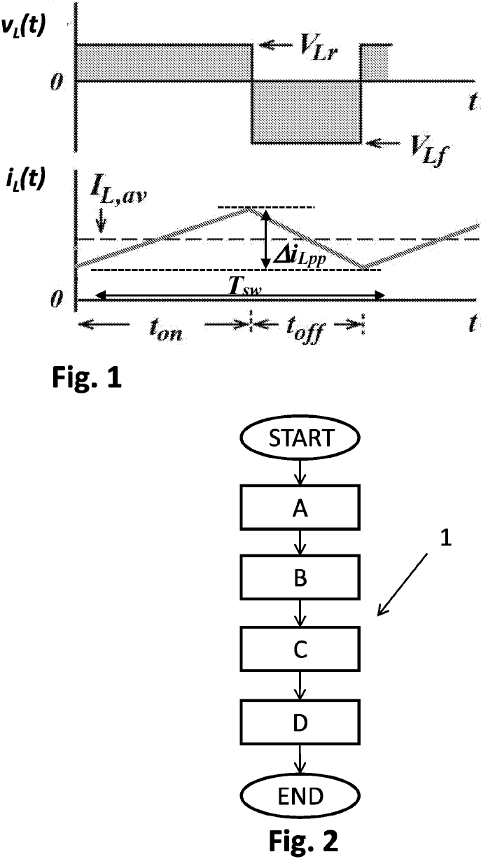

FIG. 1 shows, above, the graph of a typical voltage v_{L}(t) varying over time, that can be applied to the terminals of an inductor, for example in a PWM dc-dc converter, according to the method of the present invention and, below, the typical trend of the corresponding current i_{L}(t), that also varies in time, flowing through the inductor in response to the applied voltage v_{L}(t);

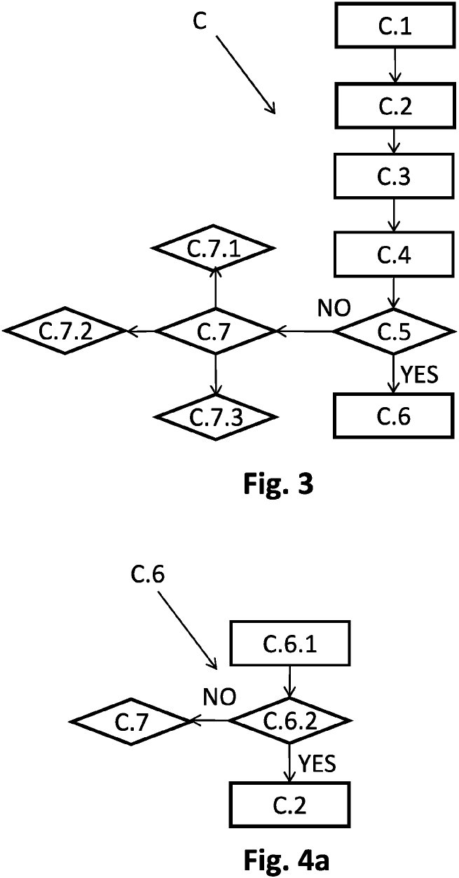

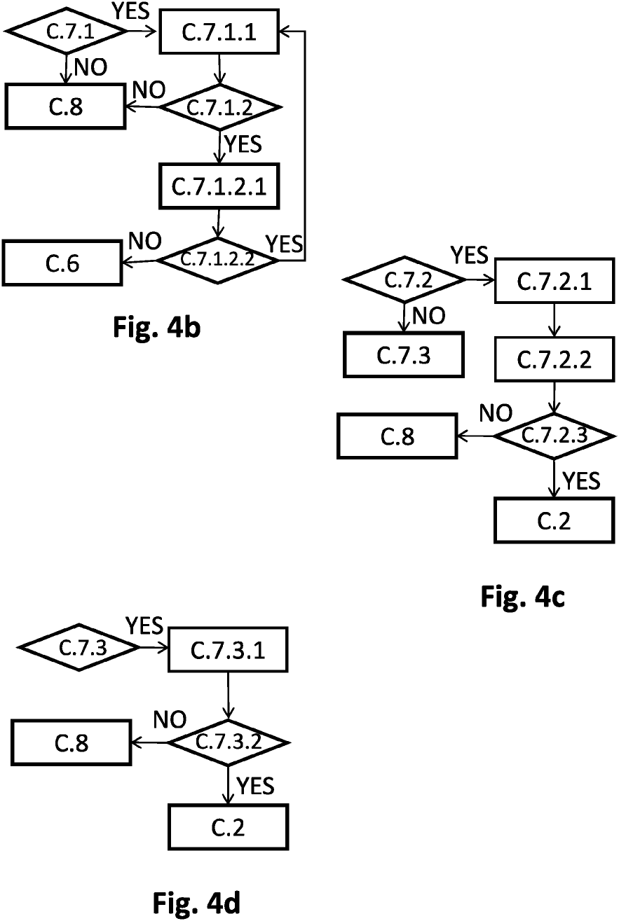

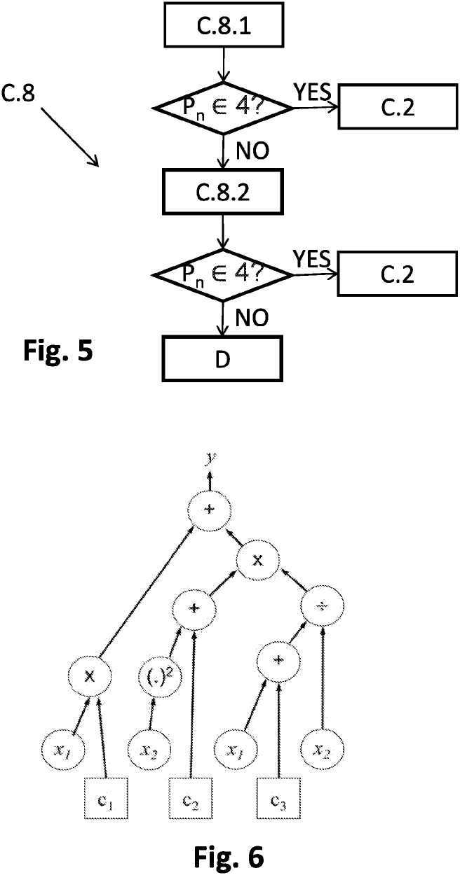

FIGS. 2 to 6 show, respectively, a block diagram of the main steps of the method according to the invention, a first, second, third, fourth, fifth and sixth detail of the steps thereof, as well as a tree structure of a preferred algorithm, which is optionally employed in said method;

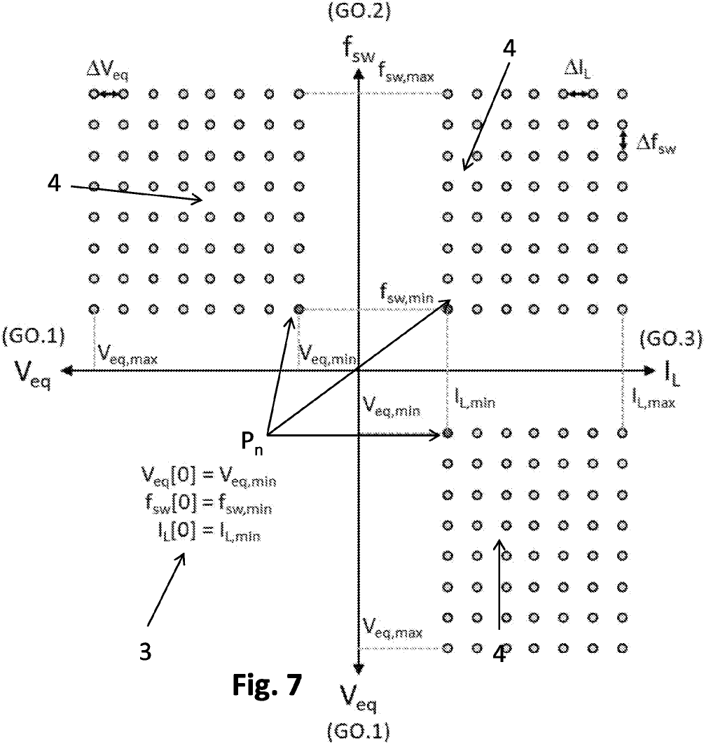

FIG. 7 illustrates a three-dimensional mathematical space and its field of exploration, defined according to the method of the invention;

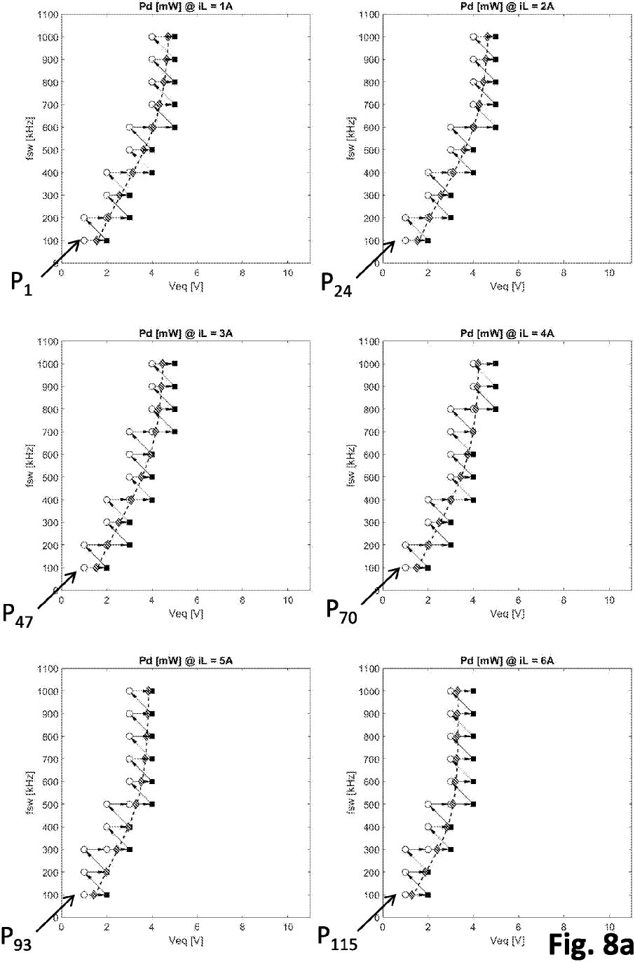

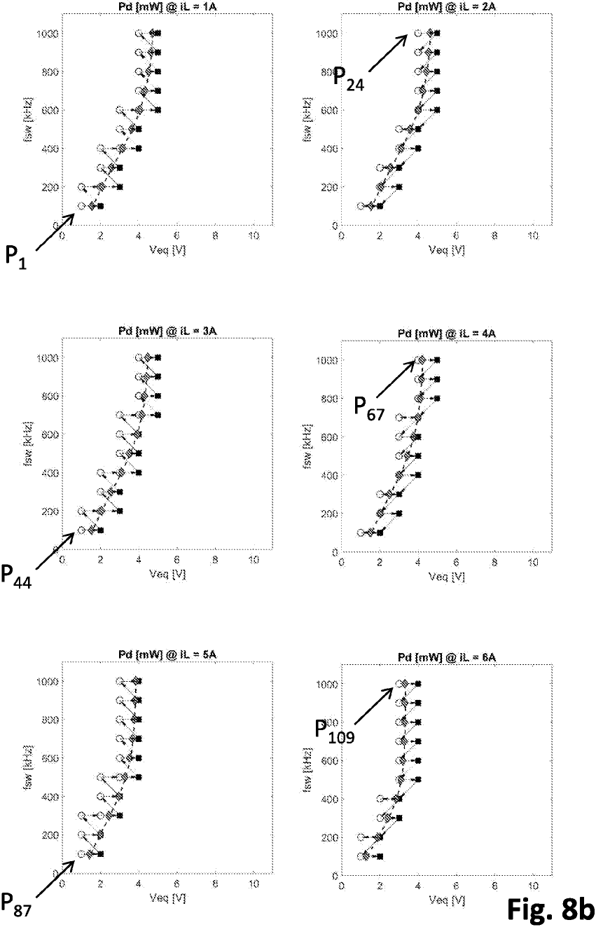

FIG. 8a is a graphical representation of an example of exploration of the field of exploration of FIG. 7, along a first and a second exploration direction, for determining the set of operational parameters of an inductor that meet a first limit condition for the inductor under investigation (specifically, that the dissipated power is P_{d}=P_{d,ref}=200 mW);

FIG. 8b is a graphical representation of a variant of the example of exploration of FIG. 8a;

FIG. 9 shows a graphical representation of an example of exploration of the field of exploration of FIG. 7, along a first and a second exploration direction, for determining the set of operational parameters of an inductor that meet a second limit condition for the inductor under investigation (specifically, that the peak-to-peak variation of the oscillation of the current flowing through the inductor is Δi_{Lpp}=Δi_{Lpp,ref}=1.0 A);

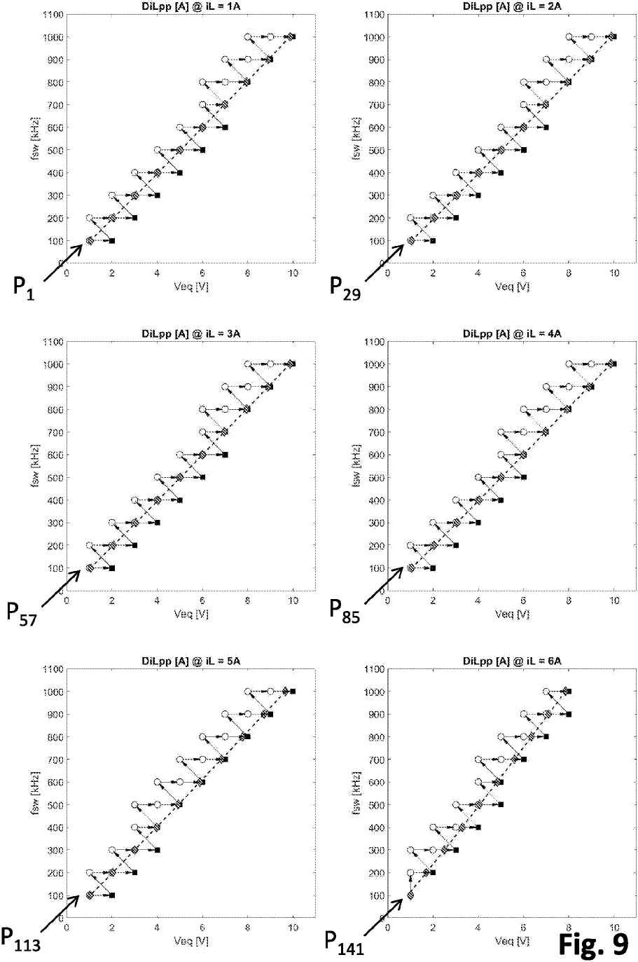

FIG. 10 is a graphical representation of an example of exploration of the field of exploration of FIG. 7, along a first and a second exploration direction, for determining the set of operational parameters of an inductor that meet a third limit condition for the inductor under investigation (specifically, that its surface temperature is Tₛ=T_{s,ref}=120° C.);

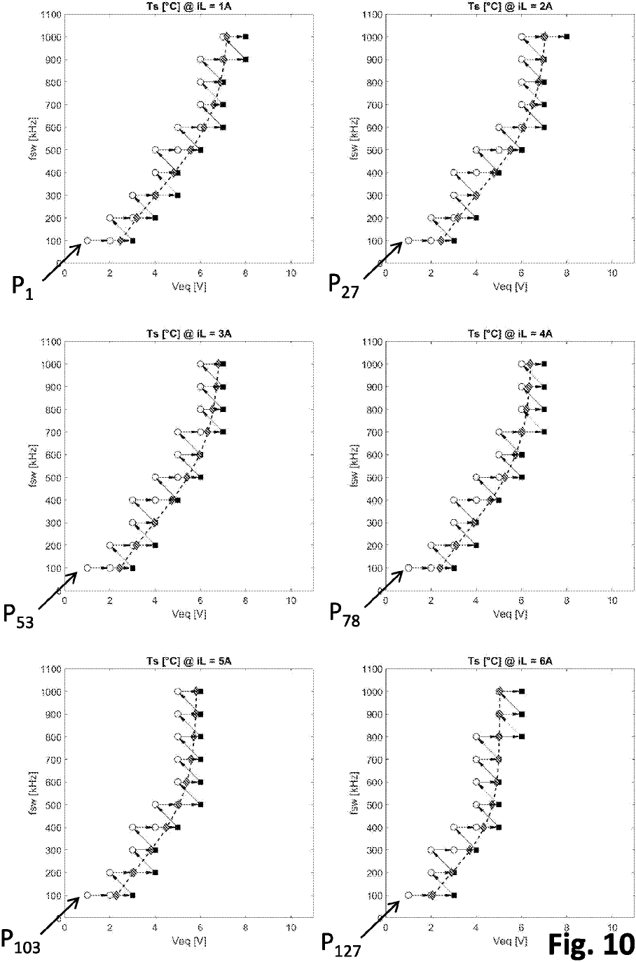

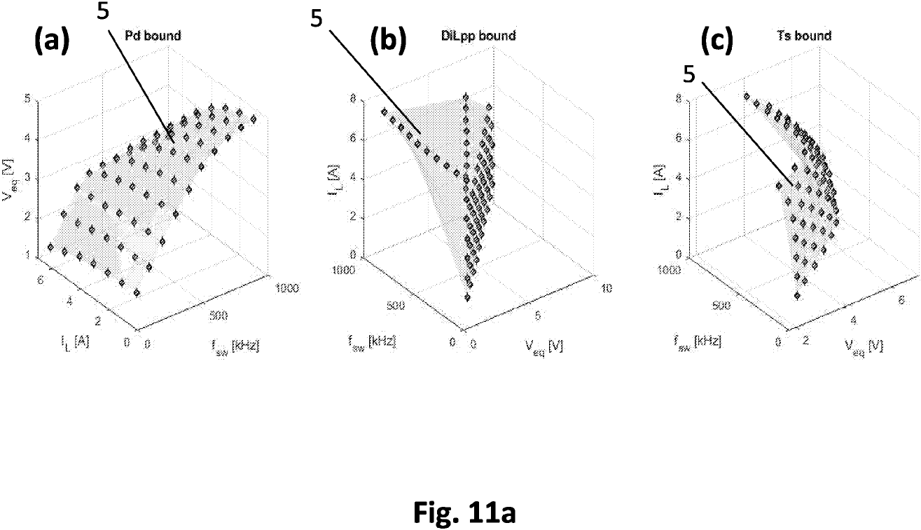

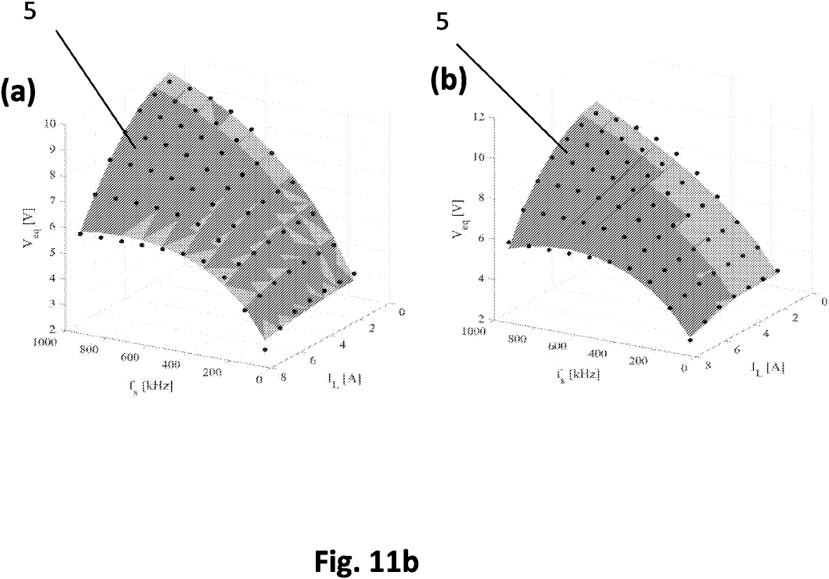

FIG. 11a is an example of a graphical representation of the locations of the operational parameters that determine an inductor response that meets, (a) the first limit condition, wherein in particular P_{d}=P_{d,ref}=200 mW, (b) the second limit condition, wherein in particular Δi_{Lpp}=Δi_{Lpp,ref}=1.0 A and (c) the third limit condition, wherein in particular Tₛ=T_{s,ref}=120° C., respectively.

FIG. 11b shows some examples of functions that describe in analytic form the locus of the operational parameters hat determine an inductor response that complies with the first limit condition, wherein in particular P_{d}=P_{d,ref}=200 mW;

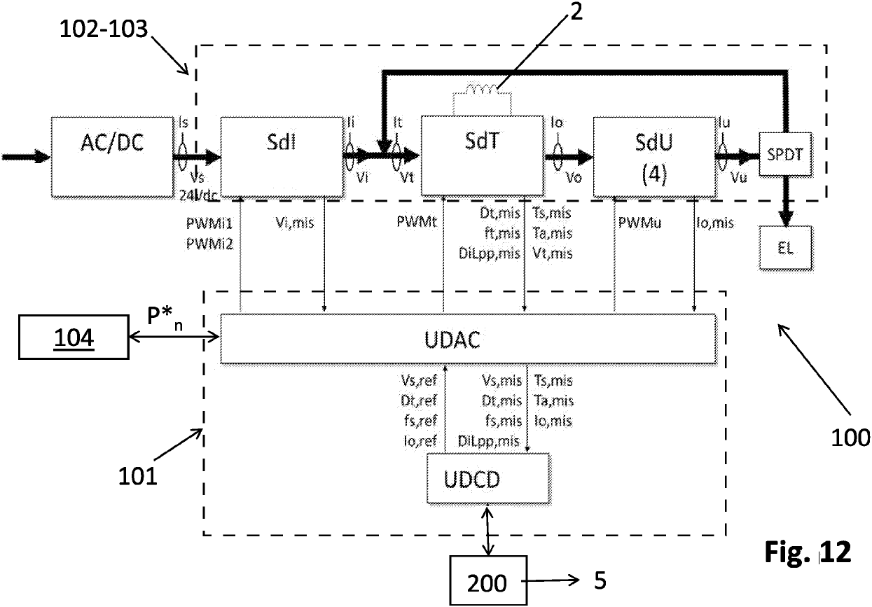

FIG. 12 shows a schematic representation of the main blocks of a measuring station that can be used for the implementation of the method according to the invention;

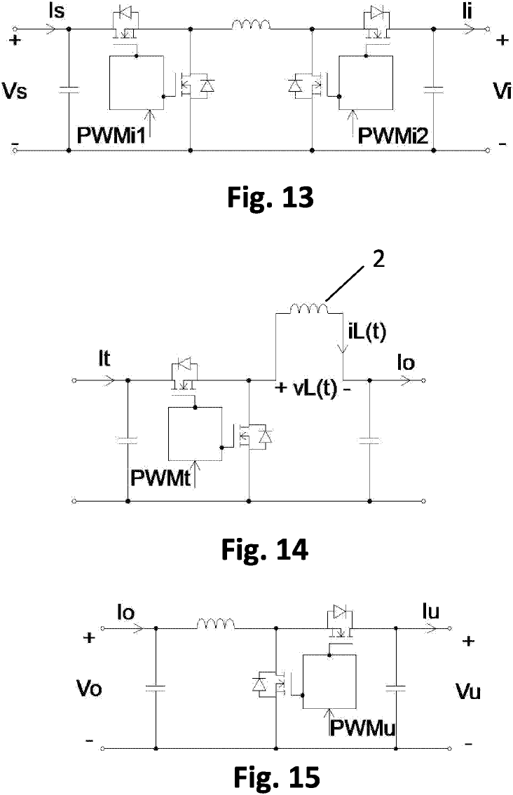

FIG. 13 illustrates a block diagram of a preferred configuration of an Input Stage of the measuring station of FIG. 12;

FIG. 14 is a block diagram of a preferred configuration of a Test Stage of the measuring station of FIG. 12, wherein the inductor under investigation is seen connected;

FIG. 15 shows a block diagram of a preferred configuration of an Output Stage of the measuring station of FIG. 12;

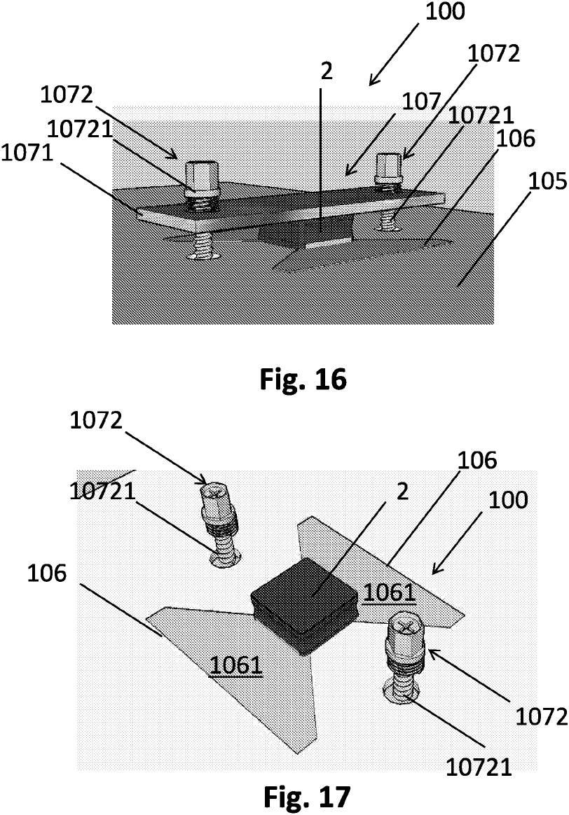

FIG. 16 illustrates a detail of the measuring station of FIG. 12, in particular of the Test Stage, on which an inductor is mounted for the implementation of the method of the present invention;

FIG. 17 is another view of the detail of FIG. 16, wherein some parts have been removed; and

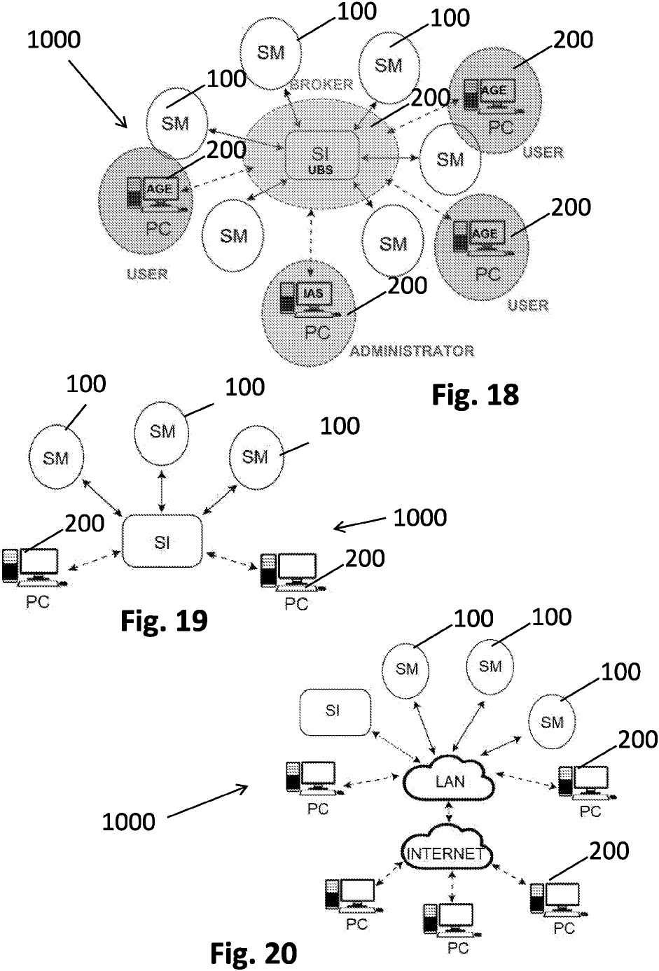

FIGS. 18 to 20 show respective configurations of a system for implementing the method of the present invention.

In the enclosed Figures the same reference numbers will be used for similar elements.

Before going into the merits of the description, it is specified that in this description the terms “inductor”, “electrical or electronic power component”, “electrical or electronic component” or “component” may be used in a completely equivalent way, that is in any case clear from the context.

It is also specified that, according to the method of the present invention, an inductor operational in an environment having temperature Tₐ, can be subjected to a stimulus comprising:
a voltage waveform v_{L}(t), to be applied to its terminals, e
an average current flowing therethrough
$${I}_{L , a v} = {f}_{s w} {\int }_{0}^{{T}_{s w}} {i}_{L} \left(t\right) d t$$
during the charge-discharge cycle.

With particular reference to FIG. 1, the waveform of the varying over time voltage v_{L}(t) that according to the method of the invention is applied to the inductor, can be defined using the following parameters:
1) a value of the positive voltage V_{Lr} applied to the inductor during the charge step (for a time interval tₒₙ);
2) a value of the negative voltage V_{Lf} applied to the inductor during the discharge step (for a time interval t_{off});
3) A frequency f_{sw}=1/(tₒₙ+t_{off})=1/T_{sw} of the repetition of the charge-discharge cycle (switching frequency)
4) a relative duration of the charging time Don = tonfsw (duty-cycle), between 0 and 1.

The response of an inductor operational at an environmental temperature Tₐ, to which the stimulus described above has been applied, i.e. a variable voltage v_{L}(t) as described above and a certain average current I_{L,av}, can be described through the following parameters, again shown in FIG. 1, namely:
1) a peak-to-peak value of the oscillation of the current Δi_{Lpp};
2) a surface temperature Tₛ of the inductor; and
3) an average electrical power P_{d} dissipated d by the inductor, according to the formula
$${P}_{d} = {f}_{s w} {\int }_{0}^{{T}_{s w}} {v}_{L} \left(t\right) {i}_{L} \left(t\right) d t .$$

This said, the method according to the present invention, indicated by reference number 1 is provided for determining the behaviour of an electrical or electronic power component (represented in FIGS. 12, 14, 16 and 17), more particularly of an inductor 2 configured to operate under typical operational conditions of power generators, and comprises (see in particular FIG. 2) one initial step A, wherein, for example through a data control and processing unit (for example represented in FIG. 12 with reference number 101 and which will be better described in the following), a three-dimensional mathematical space 3 of operational parameters of interest for the inductor 2 is defined, wherein the coordinates (pₙ₁, pₙ₂, pₙ₃) of an n-th point P of the three-dimensional mathematical space 3 correspond to specific values of the operational parameters of interest for said inductor 2.

More specifically, according to a preferred embodiment of the method of the invention, the operational parameters of interest for the inductor, the behaviour of which is to be determined, are three and are selected from:
one equivalent voltage V_{eq} to be applied to the inductor 2;
one switching frequency f_{sw} for one entire charge-discharge cycle of the inductor 2;
one average current I_{L} flowing through the inductor 2; and
one temperature Tₐ of the environment wherein the inductor 2 is operating.

On the basis of three of the above operational parameters of interest for the inductor 2, the three-dimensional mathematical space 3 is defined, according to method 1 of the invention, by assigning to each of these operational parameters of interest, a corresponding mathematical axis of a Euclidean three-dimensional mathematical space 3.

Then, method 1 according to the invention comprises a second step B, which is always performed for example by means of a data control and processing unit, wherein an exploration field 4 of the three-dimensional mathematical space 3 is defined. At step B of the invention method 1, a working limit condition of interest for the inductor and a set R of response parameters for that inductor are also defined, as will be seen below.

In this regard, according to a preferred embodiment of the invention, the exploration field 4 is defined by selecting:
one finite subset of points Pₙ of the three-dimensional mathematical space 3; and
one ordered set of three directions of exploration of the points of said exploration field 4, from any point Pₙ₋₁ to one next point Pₙ, wherein, according to a preferred embodiment of the invention, each direction of exploration is optionally parallel to a respective axis of the three-dimensional mathematical space 3.

According to a particularly advantageous aspect of the invention, the coordinates of the points Pₙ of the exploration field 4 assume values between a minimum value and a maximum value of the respective operational parameters (V_{eq}, fs_{w}, I_{L}). Specifically, therefore:
V_{eq} can vary between a minimum value V_{eq,min} and a maximum value V_{eq,max};
f_{sw} can vary between a minimum value f_{sw,min} and a maximum value f_{sw,max};
I_{L} can vary between a minimum value I_{L,min} and a maximum value I_{L,max}; and
Tₐ can vary between a minimum value T_{a,min} and a maximum value T_{a,max}.

Within the finite set of points Pₙ that make up the exploration field 4 there will be, therefore, a point with minimum coordinates, for example given by (V_{eq,min}, f_{sw,min}, I_{L,min}) and a point of coordinates maximum, for example (V_{eq,max}, f_{sw,max}, I_{L,max}) at a given environmental temperature Tₐ.

The finite number of points Pₙ included in the exploration field 4 is a function, for each of the exploration directions of the three-dimensional mathematical space 3, of:
a number of samples (N_{Veq}, N_{fsw}, N_{IL}); and
one offset (ΔV_{eq}, Δf_{sw}, ΔI_{L}) between one sample and the next one along the respective direction of exploration.

In other words, the number of samples (N_{Veq}, N_{fsw}, N_{IL})and the offset (ΔV_{eq}, Δf_{sw}, ΔI_{L}) for each one of the three directions of exploration, determine the coordinates, within the mathematical space 3, of the points Pₙ included in the exploration field 4.

Specifically, according to method 1 of the present invention, for each one of the three directions of exploration of the exploration field 4, the number of samples (N_{Veq}, N_{fsw}, N_{IL}) can be predetermined and the offset (ΔV_{eq}, Δf_{sw}, ΔI_{L}) can be also prefixed and constant, or the number of samples (N_{Veq}, N_{fsw}, N_{IL}) can be prefixed while the offset (ΔV_{eq,i}, Δf_{sw,j}, ΔI_{L,k}) with i = 1,..,N_{Veq}-1, j = 1,..,N_{fsw}-1, k = 1,..,N_{IL}-1, between two consecutive samples (corresponding to two consecutive points Pₙ₋₁ and Pₙ of the exploration field 4) can vary, optionally according to a selection between a logarithmic, power, trigonometric, transcendent or predetermined numerical series function. According to a further variant of method 1 of the invention, the number of samples (N_{Veq}, N_{fsw}, N_{IL}) may not be predetermined and may depend on an offset (ΔV_{eq,i}, Δf_{sw,j}, ΔI_{L,k},) with i = 1, ..N_{Veq}-1, j = 1,..,N_{fsw}-1, k = 1,..,N_{IL}-1, that varies between one sample and the next one, which is calculated each time during the exploration of the exploration field 4, for each point Pₙ, optionally based on a value assumed by a set R of response parameters (which will be better described below), calculated at previously explored points Pₙ₋₁ and Pₙ₋₂ of the exploration field 4.

At the end of step B, the method 1 of the invention comprises at step C to explore the three-dimensional mathematical space 3, starting from a starting point included in the exploration field 4 defined as above, in search of points P of the three-dimensional mathematical space 3 that meet at least one working limit condition for inductor 2. As will be seen in detail below, the exploration of the three-dimensional mathematical space 3 takes by means of:
the generation of at least one stimulus, determined based on the coordinates of points Pₙ of the three-dimensional mathematical space 3 and based on the exploration field 4,
the application of that stimulus to the inductor 2, and
the detection of a correspondent response of said inductor 2 to said stimulus thereby applied. Based on the response thus detected, step C of invention method 1 also comprises determining and storing a finite subset of points P*ₙ of the three-dimensional mathematical space 3, among the points Pₙ of the mathematical space for which the working limit condition of the inductor 2 is met.

More particularly, the exploration of the exploration field 4 is carried out in an orderly way (as will be better disclosed below), starting from one starting point Pₙ of said exploration field 4, along the directions of exploration of the ordered set of directions for exploration and according to one exploration rule such that the coordinates of an explored n-th point Pₙ of said three-dimensional mathematical space 3 differ from those of a previous point Pₙ₋₁, for the value of one or more of its components. Thus, for example:
if the parameters of interest for an inductor to be examined are, in order V_{eq}, f_{sw} and I_{L};
if in the three-dimensional mathematical space 3 a exploration field 4 is defined wherein V_{eq} varies between V_{eq,min} and V_{eq,max}, f_{sw} varies between f_{sw,min} and f_{sw,max} and I_{L} varies between I_{L,min} and I_{L,max};
if the exploration field 4 is explored starting from a starting point P₁ having coordinates (V_{eq,min}, f_{sw,min}, I_{L,min}); and
assuming that the offsets between one point and another of the exploration field 4 are constant and predetermined;
then the point P₂, subsequently explored according to method 1 of the present invention, can have one of the following coordinates (V_{eq,min}±ΔV_{eq}, f_{sw,min}, I_{L,min}), if the exploration is along the first direction of exploration, or (V_{eq,min}, f_{sw,min}±Δf_{sw}, I_{L,min}), if the exploration is along the second exploration direction, or (V_{eq},ₘᵢₙ, f_{sw},ₘᵢₙ, I_{L,min}±ΔI_{L}), if the exploration is along the third direction of exploration. That is, as mentioned above, each point differs from the previous one by the value of only one component of its coordinates.

According to a variation of the method 1 of the present invention, the exploration of the exploration field 4 can also be performed according to a different exploration rule for which the coordinates of an n-th point Pₙ differ from those of the previous point Pₙ₋₁, for the value assumed by two or all three components. For example, according to a variation of the method of the present invention, the exploration of the exploration field 4 can be performed over parallel planes wherein, then, the points Pₙ of the exploration field 4, which lie on a plane parallel to the one on which two axes of three-dimensional mathematical space 3 lie, are first explored starting from a starting point of minimum coordinates (for example starting from P₁ having coordinates (V_{eq,min}, f_{sw,min}, I_{L,min}) until a point Pₙ of maximum coordinates in that plane is reached (thus arriving at a point of coordinates (V_{eq,max}, f_{sw,max}, I_{L,min}) and then passing to the adjacent parallel plane and exploring this adjacent parallel plane starting from a point with minimum coordinates in that plane Pₙ₊₁= (V_{eq,min}, f_{sw,min}, I_{L,min}+ΔI_{L}). It is understood that the one provided is a purely indicative and non-limiting example for the present invention and the person skilled in the art will have no difficulty in understanding how it is possible to explore the points of the exploration field 4 also in other ways, for example starting from a point of maximum coordinates for the field of exploration or in a plane thereof as described above.

With regard to the working limit condition, it is specified that whether or not that working limit condition is met in any point Pₙ of the three-dimensional mathematical space 3 (including those of the exploration field 4) depends on the value assumed by at least one response parameter of the set R of response parameters of the inductor 2, following the application to its terminals of at least one stimulus as described above (i.e. comprising a square wave voltage v_{L}(t) and an average current I_{L}), and by a pre-set search logic, as explained below.

The response parameters that are comprised in the above said set R are one or more between:
a peak-to-peak variation (Δi_{Lpp}) of the current (i_{L}(t)) varying over time flowing through inductor 2;
a surface temperature (Tₛ) of the inductor; and
an average electrical power (P_{d}) dissipated by the inductor 2.

It should be noted that, according to a preferred embodiment of the invention, the aforementioned response parameters can be detected by a detecting device included in a measuring station which also forms part of the present invention, and which will be described below. More particularly, the peak-to-peak variation of the time-varying current(i_{L}(t)) flowing through the inductor and the surface temperature Tₛ can be directly detected by respective analog components of the detecting device, while the dissipated power P_{d} can be calculated as a function of the stimulus variable voltage v_{L}(t) applied to the inductor 2 and the variable current i_{L}(t) detected by it. Alternatively, according to a variant of the present invention, the dissipated power P_{d} can also be determined in an alternative way. For example, according to a variant of the present invention, the dissipated power P_{d} can be determined in a more approximate but still reliable way, as a function of the surface temperature Tₛ of the inductor 2, in a way known to the man skilled in the art.

According to method 1 of the invention, the aforementioned working limit condition for inductor 2 is a function of a threshold value (Δi_{Lpp,ref}, T_{s,ref}, P_{d,ref}) for a corresponding response parameter. More particularly, the working limit condition is met if one or more response parameters assume a value lower than or equal to the respective threshold value Δi_{Lpp,ref}, T_{s,ref}, P_{d,ref}).

As far as the search logic is concerned, the working limit condition for the points P of the three-dimensional mathematical space 3 can concern, as mentioned above:
(i) only one response parameter of the set R of response parameters; or
(ii) jointly more than one of the response parameters of the set R of response parameters, as mentioned above, corresponding to the peak-to-peak value of the current oscillation Δi_{Lpp}, or the inductor surface temperature Tₛ, or the average electrical power P_{d} dissipated by the inductor.

In other words, the exploration of three-dimensional mathematical space 3 can be carried out by considering three distinct working limit conditions according to the following different search logics:
1) a first search logic, according to which three distinct sets of points P of the three-dimensional mathematical space 3 are identified, each set complying with only one of the working limit condition;
2) a second search logic, according to which three distinct sets of points P of the three-dimensional mathematical space 3 are identified, each set complying with one among the possible pairs of working limit conditions;
3) a third search logic, according to which the set of points P of the three-dimensional mathematical space 3 is identified, the points jointly complying with all three working limit conditions.

According to an advantageous embodiment of the invention, the search logic is selected at step B or in any case before the execution of step C of invention method 1. Alternatively, the search logic can be pre-set.

Going into the merits of step C of method 1 of the present invention, it comprises:
C.1 selecting one starting point Pₙ comprised in said exploration field 4 and one first direction of exploration of said exploration field 4;
C.2 generating, by means of a stimulus generation device (which will also be discussed below), one stimulus comprising a varying over time voltage v_{L}(t) and a constant average current I_{L}, based on the value of the coordinates of the just selected point Pₙ, and applying the stimulus thus generated to inductor 2;
C.3 detecting at the terminals of inductor 2, by means of the detecting device, in response to the stimulus thus applied, at least one varying over time current i_{L}(t) and the surface temperature of the inductor (Tₛ);
C.4 determining, through the data control and processing unit, said set R of response parameters, based on the corresponding detected varying over time current (i_{L}(t)) and the inductor surface temperature (Tₛ); and
C.5 comparing, through said data control and processing unit, each element of said set R of response parameters with said working limit condition; and
C.6 if said working limit condition is met at point Pₙ:
   C.6.1 selecting a new point Pₙ of the three-dimensional mathematical space 3, along the first selected direction of exploration; and
   C.6.2 if the new point Pₙ is comprised within the field of exploration 4, going back to step C.2;
   Otherwise going to step C.8
C.7 if said working limit condition is not met at point Pₙ:
   C.7.1if the point Pₙ just selected is the starting point of said exploration field 4:
      C.7.1.1 selecting a new point Pₙ of the three-dimensional mathematical space 3, along the first selected direction of exploration; and
      C.7.1.2 if the new point Pₙ is comprised within said exploration field 4:
         C.7.1.2.1 carrying out steps C.2-C.5 and
         C.7.1.2.2 if said working limit condition is not met in the new point Pₙ of the three-dimensional mathematical space 3, going back to step C.7.1.1;
         otherwise going back to step C.6
      otherwise going to step C.8
      otherwise
   C.7.2 if the point Pₙ just selected and the point Pₙ₋₁ previous to that are placed along the first direction of exploration:
      C.7.2.1 determining, through the data control and processing unit, and storing, in a storage unit, the coordinates (p*ₙ₁, p*ₙ₂, p*ₙ₃) of another point P*ₙ of the three-dimensional space 3, that is comprised in the neighbourhood of point Pₙ of said exploration field 4, along said first selected direction of exploration, wherein said working limit condition is met;
      C.7.2.2 selecting previous point Pₙ₋₁ and, starting from that, a new point Pₙ, of the three-dimensional mathematical space 3 along the second direction of exploration; and
      C.7.2.3 if the newly selected point Pₙ is comprised within said exploration field 4, going back to step C.2;
      otherwise going to step C.8
      otherwise
   C.7.3 if the point Pₙ just selected and the point Pₙ₋₁ previous to that are placed along the second direction of exploration:
      C.7.3.1 selecting a new point Pₙ of the three-dimensional mathematical space 3, along the first direction of exploration; and
      C.7.3.2 if the newly selected point Pₙ is comprised within said exploration field 4, going back to step C.2;
      otherwise, going to step C.8;
C.8 if the point Pₙ just selected is not comprised within said exploration field 4:
   C.8.1 selecting, along the second direction of exploration, a new point Pₙ of the three-dimensional mathematical space 3, starting from the previously selected point Pₙ₋₁ and, if the newly selected point Pₙ is comprised within said exploration field 4, going back to step C.2; otherwise
   C.8.2 selecting, along the third direction of exploration, the new point Pₙ of the three-dimensional mathematical space 3, starting from the previously selected point Pₙ₋₁ and, if the newly selected point Pₙ is comprised within said exploration field 4, going back to step C.2; otherwise going to the following step (step D) which will be described below.

With particular reference to the above-mentioned step C.7.2.1, according to a preferred embodiment of method 1 of the present invention, it is envisaged that the stored coordinates of each point P*ₙ of the mathematical space 3, which is included in the neighbourhood of said point Pₙ of the exploration field 4, can be calculated, by means of an interpolation formula, optionally a linear one. Specifically in the aforementioned case wherein:
the parameters of interest for an inductor to be examined are, in order V_{eq}, f_{sw} e I_{L};
in the three-dimensional mathematical space 3 a exploration field 4 is defined wherein V_{eq} varies between V_{eq,min} and V_{eq,max}, f_{sw} varies between f_{sw,min} and f_{sw,max} and I_{L} varies between I_{L,min} and I_{L,max};
if that exploration field 4 is first explored along the first exploration direction, so that a previous point Pₙ₋₁ has coordinates (V_{eq}[n-1], f_{sw}[n-1], I_{L}[n-1]) and a point Pₙ has coordinates (V_{eq}[n-1]+ ΔV_{eq}, f_{sw}[n-1], I_{L}[n-1]), the coordinates of the new point P*ₙ to be stored (V*_{eq}, f_{sw}[n-1], I_{L}[n-1]) are given by:
$${V}_{e q}^{∗} = \left\{\begin{matrix}{V}_{e q} \left[n - 1\right] + \frac{Δ {i}_{L p p , r e f} - Δ {i}_{L p p} \left[n - 1\right]}{Δ {i}_{L p p} \left[n\right] - Δ {i}_{L p p} \left[n - 1\right]} Δ {V}_{e q} & s e Δ {i}_{L p p} \left[n\right] > Δ {i}_{L p p , r e f} \\ {V}_{e q} \left[n - 1\right] + \frac{{P}_{d , r e f} - {P}_{d} \left[n - 1\right]}{{P}_{d} \left[n\right] - {P}_{d} \left[n - 1\right]} Δ {V}_{e q} & s e {P}_{d} \left[n\right] > {P}_{d , r e f} \\ {V}_{e q} \left[n - 1\right] + \frac{{T}_{s , r e f} - {T}_{s} \left[n - 1\right]}{{T}_{s} \left[n\right] - {T}_{s} \left[n - 1\right]} Δ {V}_{e q} & s e {T}_{s} \left[n\right] > {T}_{s , r e f}\end{matrix}\right)$$
depending on which of the response parameters of the set R of the response parameters does not comply with the limit condition.

Of course, if the exploration of the exploration field 4 was along the second or third direction of exploration, instead of V_{eq} and ΔV_{eq}, the above formula would involve, respectively, f_{sw} with Δf_{sw} and I_{L} with ΔI_{L}

Once the coordinates of a point P*ₙ have been determined, the above method 1 foresees, at step C.7.2.2, to select the previous point Pₙ₋₁ and, starting from this, a new point Pₙ in the mathematical space 3 along the second exploration direction, where the coordinates of the new point are given by (V_{eq}[n-1], f_{sw}[n-1]+ Δf_{sw}, I_{L}[n-1]) or ((V_{eq}[n-1], f_{sw}[n-1]- Δf_{sw}, I_{L}[n-1]) depending on the case. In fact, depending on which starting point is chosen, for the exploration of the exploration field 4, the values of the components of the coordinates of the points Pₙ included therein will be increased or reduced, to allow the method of the present invention to explore and select the points of three-dimensional mathematical space 3, starting from those of the exploration field 4, which comply with the working limit condition.

At step C.7.3.1 of method 1 of the invention, on the other hand, a new point Pₙ is selected in mathematical space 3 along the first direction of exploration, where the coordinates of the new point are determined starting from Pₙ and are given by (V_{eq}[n] ]+ΔV_{eq}, f_{sw}[n], I_{L}[n]) or (V_{eq}[n] - ΔV_{eq}, f_{sw}[n], I_{L}[n]) depending on the case. In this case also, in fact, depending on which starting point is chosen, for the exploration of the exploration field 4, the values of the coordinates of the points Pₙ included therein will be increased or reduced, to allow the method of the present invention to explore and select the points of three-dimensional mathematical space 3, starting from those of the exploration field 4, which comply with the working limit condition.

In other words, and as will also be seen in the following, the three-dimensional mathematical space 3 is explored, starting from the points of the exploration field 4, around its boundary surface which divides the three-dimensional mathematical space 3 into two half-spaces, one having points wherein the working limit condition is met and another having points wherein the working limit condition is not met.

The aforementioned step C.8 is about the case wherein a new selected point Pₙ of the mathematical creation space 3 is not included in the exploration field 4 has, that is, wherein a component of its coordinates is outside the range of minimum and maximum values mentioned above, for example in the case wherein the exploration of the exploration field 4 is carried out along the first exploration direction and the new point Pₙ has coordinates (V_{eq,max}[n] +ΔV_{eq}, f_{sw}[n], I_{L}[n]). Method 1 of the present invention comprises selecting a new point Pₙ of the three-dimensional mathematician, starting from this previously selected point Pₙ, along the second direction of exploration (step C.8.1) and, if this point Pₙ is included in the field exploration, the method returns to step C.2; otherwise the method 1 of the invention comprises selecting the new point Pₙ of the mathematical space, starting from the previously selected point Pₙ₋₁, along the third direction of exploration (step C.8.2) and, if the point direction of exploration is included in the exploration field 4, the method returns to step C.2. According to a further alternative, when the points Pₙ of the exploration field 4, that are located around the boundary surface have all been explored, the method can continue to the next step (step D).

As anticipated above at step C.7.1 of the invention method, if during the execution of method 1 it is found, only for the initial point Pₙ of the exploration field 4, that the working limit condition is not met, the method comprises searching for the first point Pₙ of the exploration field 4 wherein the working limit condition is met, along the first direction of exploration. In other words, at the start of the invention method 1, the exploration field 4 is explored in search of a boundary point of the three-dimensional mathematical space 3, at which the inductor 2 has a behaviour that complies with the aforementioned working limit condition.

It should be noted that thanks to the guided exploration of the exploration field 4 at step C, the method 1 of the present invention allows selecting a finite number of points (or combinations of operational parameters) within the mathematical space 3, for which the inductor 2 complies with at least one limit condition (which typically corresponds to a threshold within which inductor 2 works in compliance with the working limit condition). The number of points of the exploration field 4 at which the exploration is actually carried out can be, depending on the case, much lower than the total number of points of the same exploration field 4, so that with the method 1 of the present invention the computational complexity required to determine the behaviour of inductor 2 is considerably reduced.

Purely by way of a non-limiting example, reference is made to FIGS. 7 to 10, wherein a search sequence carried out in the three-dimensional mathematical space 3 is illustrated, for a power inductor 2 having known characteristics, the fixed response conditions of which being:
Δi_{Lpp,ref}=1.0 A;
T_{s,ref}=120° C., and
P_{d,ref}=200 mW.

In the provided example, therefore, the three-dimensional mathematical space 3 is explored in search of the points P*ₙ (i.e., triples of operational parameters V_{eq}, f_{sw}, i_{L}) which constitute the boundary of the region (half-space) of the three-dimensional mathematical space 3, wherein the aforementioned predetermined working limit condition is valid.

The operational parameters of interest are V_{eq}, f_{sw} and I_{L} and vary in the ranges V_{eq,range} = [ 1 V, 10 V ], f_{sw,range} = [ 100 kHz, 1 MHz ] and I_{L,range} = [ 1 A, 6 A ], with uniform offsets of the operational quantities having amplitude equal to ΔV_{eq} = 1 V, Δf_{sw} = 100 kHz, ΔI_{L} = 1 A. The exploration field 4 is explored, in FIGS. 8b to 10, starting from starting point P₁= (V_{eq,min}, f_{sw,min}, I_{L,min}) according to a first exploration direction parallel to the abscissa axis and a second direction of exploration parallel to the ordinate axis. The third direction of exploration is represented by the sequence of graphs where we go from i_{L}=1 A to i_{L}= 6 A.

In the graphs illustrated at FIGS. 8a, 9 and 10:
the dotted lines represent the actual operational limits of the component under investigation, corresponding to the above indicated set working limit conditions set,
the white circles identify explored points P ₙ of the exploration field 4, wherein the limit condition is met,
the black squares identify explored points P ₙ of the exploration field 4, wherein the working limit condition is not met,
the grey rhombuses identify points P* ₙ of three-dimensional mathematical space 3 obtained through the interpolation formula above, which correspond to limit values of the operational parameter V_{eq}, given the values of the operational parameters f_{sw} e I_{L} at which the working limit condition is still met.

The result of the exploration is a list of coordinates of points P*ₙ of mathematical space 3 (corresponding to triplets of operational parameters for the inductor 2 of interest), wherein the working limit condition Δi_{Lpp}=Δi_{Lpp,ref} and/or Tₛ=T_{s,ref} e/o P_{d}=P_{d,ref} in met. With reference to the example of FIGS. 8a-8b, 9 and 10, the aforementioned list of coordinates represents the operational parameters that determine an inductor response wherein the power dissipation is P_{d}=P_{d,ref}=200 mW, a response of the inductor wherein the peak-to-peak current ripple is Δi_{Lpp}=Δi_{Lpp,ref}=1.0 A and an inductor response wherein the surface temperature is Tₛ=T_{s,ref}=120° C., respectively, in the case where an environmental temperature is equal to 40° C. In other words, each search carried out with reference to a specific working limit condition (search logic referred to in point 1) above) generates a corresponding specific list of triplets. That list of triplets identifies a certain surface in the three-dimensional mathematical space 3 having axes V_{eq}, f_{sw}, I_{L}. Surfaces 5(a), 5(b) and 5(c) shown in FIG. 11a identify the location of the grey rhombuses of FIG. 8, FIG. 9, and FIG. 10, respectively. It is of note that in FIGS. 8a to 10, the arrows represented there, which connect the white circles, the black squares and the grey rhombuses to each other only provide for a visual indication of the order wherein the points of the three-dimensional mathematical space 3 are explored. In the example shown above, the exploration of the aforementioned points requires that within a single plane of three-dimensional mathematical space 3 (represented by one of the six frame of each Figure), only one of the coordinates varies at a time, along a single direction for exploration, as described above, between a selected point and the next one. When moving between one plane of mathematical space 3 and a plane adjacent thereto, it can be foreseen that the points of the exploration field 4 are always explored starting from the one with lower coordinates (closest to the origin of the axes - FIGS. 8a, 9 and 10). In this case, the values of all three coordinate components change between the last point of a plane and the first point of the adjacent plane. Alternatively, as illustrated in FIG. 8b, it can be expected that, between the last point of one plane and the first point of the adjacent plane, only the value of a component of the coordinate’s changes. In this case, as can be seen in FIG. 8b, while in the frames on the left the arrows follow a substantially ascending path, in the right frames the arrows follow a substantially descending path.

The method 1 of the present invention after step C, comprise the execution of step D wherein a mathematical model is determined, for example by means of the data control and processing unit, in the three-dimensional mathematical space 3, the mathematical model describing in analytic form the locus of the points P*ₙ thus stored, thereby obtaining a locus 5 of the operational parameters which determine a response in the inductor 2 which compiles with the working limit condition.

What is obtained, therefore, is an analytical description of the surface 5 of the three-dimensional mathematical space 3 which surface divides this space into two half-spaces: a first half-space, which defines the operational conditions at which inductor 2 operates in compliance with the working limit condition, and another half-space opposite to the first half-space with respect to surface 5, which defines the operational conditions at which the inductor 2 does not operate in compliance with the working limit condition.

According to a particularly advantageous embodiment of the invention, step D of method 1 includes the application of at least one algorithm, for example of Genetic programming algorithm (J. R. Koza, Genetic Programming: On the Programming of Computers by Means of Natural Selection, MIT Press, Cambridge, 1992), to above mentioned points P*ₙ stored during the previous step. It is quite clear, in this regard, that more than one algorithm belonging to the Genetic programming family of algorithms can be used for the execution of step D of the method according to the present invention. For example, instead of a preferred algorithm that will be disclosed by way of non-limiting example in the following, a Cartesian Genetic Programming algorithm (J.F. Miller, Cartesian Genetic Programming, Springer, ISBN 978-3-642-17310-3) or, alternatively to this algorithm family, a Grammatical Evolution algorithm (C. Ryan, M. O′Neill, Michael, J.J. Collins, Handbook of Grammatical Evolution, Springer, ISBN 978-3-319-78717-6), can be used, provided that such an algorithm is able to obtain a mathematical model that analytically describes the locus of the stored P*n points and, therefore, a locus 5 of the operational parameters which determine a response in the inductor 2 compiling with the working limit condition.

With reference to FIGS. 8a to 10, at step D of method 1 of the present invention the aforementioned algorithm is applied to the points P*ₙ i.e., to the grey rhombuses of FIG. 11a whose coordinates have been stored in the storage unit.

According to a preferred example of method 1 of the present invention, the Genetic Programming algorithm allows to obtain a function that analytically describes the locus of the operational parameters that determine an inductor response characterized by a certain value of the peak-to-peak current ripple Δi_{Lpp}=Δi_{Lpp,ref} and/or its surface temperature Tₛ=T_{s,ref} and/or its dissipated power P_{d}=P_{d,ref}, starting from the varying over time response of inductor 2 (i.e. from the current i_{L}(t)) experimentally acquired through a hardware system which will be described below, which is also the subject of the invention.

Therefore, as already mentioned above, the method 1 of the invention does not require the exhaustive execution of experimental tests on an entire mathematical space or three-dimensional domain of the values of the operational quantities {V_{eq}, f_{sw}, I_{L}}, but only on a very reduce subset of their combinations. To provide an example, if the exploration field 4 included 10 samples for each of the operational quantities {V_{eq}, f_{sw}, I_{L}}, compared to 1000 possible combinations (points Pₙ), the method of the present invention would test about 200 points.

A Genetic Programming algorithm that can be advantageously used in the invention method 1 can be developed ad hoc or provided by software widely used in the field, for example MatLAB. Such an algorithm, as is known, adopts for the representation of a mathematical model a tree structure like the one shown, by way of example, in FIG. 6 and described by the equation:

$$y = {c}_{1} {x}_{1} + \left({c}_{2} + {x}_{2}^{2}\right) \frac{{x}_{1} + {c}_{3}}{{x}_{2}}$$

The tree that represents the mathematical model that is automatically generated by the Genetic Programming algorithm, providing as input a given set of elementary functions that operate on constant coefficients (c₁, c₂ e c₃) and independent variables (x₁ and x₂).

In the case of the present invention, the pair of input variables (x₁, x₂) can be associated, through the data control and processing unit referred to above, to any pair of the above operational parameters ((V_{eq}, f_{sw}), (f_{sw}, I_{L}) or (V_{eq}, I_{L}), while the output can be associated with the remaining third operational parameter. The coefficients c₁, c₂, ... depend on the working limit condition of the inductor 2 under investigation, Δi_{Lpp}=Δi_{Lpp,ref}, or Tₛ=T_{s,ref}, or P_{d}=P_{d,ref}, for which the operational parameters triplet list has been generated, which describe a surface in the three-dimensional mathematical 3 space {V_{eq}, f_{sw}, I_{L}} identified by the combinations of operational parameters at which a limit condition is compiled with. It follows that the Genetic programming algorithm can generate nine different mathematical models, three for each inductor response parameter, as follows:
M.1. V_{eq} model as a function of f_{sw} and I_{L} for a set P_{d}:
$${\text{V}}_{\text{eq}} {\text{=f}}_{\text{Veq,Pd}} \left({\text{f}}_{\text{sw}} \text{,} {\text{I}}_{\text{L}} \text{,} {\text{c}}_{\text{Veq,1}} \left({\text{P}}_{\text{d,ref}}\right) \text{,} {\text{c}}_{\text{Veq,2}} \left({\text{P}}_{\text{d,ref}}\right) \text{,} …\right)$$
M.2. f_{sw} model as a function of V_{eq} and I_{L} for a set P_{d}:
$${\text{f}}_{\text{sw}} = {\text{f}}_{\text{fsw,Pd}} \left({\text{V}}_{\text{eq}} \text{,} {\text{I}}_{\text{L}} \text{,} {\text{c}}_{\text{fsw,1}} \left({\text{P}}_{\text{d,ref}}\right) \text{,} {\text{c}}_{\text{fsw,2}} \left({\text{P}}_{\text{d,ref}}\right) \text{,} …\right)$$
M.3. I_{L} model as a function of V_{eq} and f_{sw} for a set P_{d}:
$${\text{I}}_{\text{L}} = {\text{f}}_{\text{IL,Pd}} \left({\text{V}}_{\text{eq}} \text{,} {\text{f}}_{\text{sw}} \text{,} {\text{c}}_{\text{IL,1}} \left({\text{P}}_{\text{d,ref}}\right) \text{,} {\text{c}}_{\text{IL,2}} \left({\text{P}}_{\text{d,ref}}\right) \text{,} …\right)$$
M.4. V_{eq} model as a function of f_{sw} and I_{L} for a set Δi_{Lpp}:
$${\text{V}}_{\text{eq}} = {\text{f}}_{\text{Veq,} \text{Δ} \text{iLpp}} \left({\text{f}}_{\text{sw}} \text{,} {\text{I}}_{\text{L}} \text{,} {\text{c}}_{\text{Veq,1}} \left(\text{Δ} {\text{i}}_{\text{Lpp,ref}}\right) \text{,} {\text{c}}_{\text{Veq,2}} \left(\text{Δ} {\text{i}}_{\text{Lpp,ref}}\right) \text{,} …\right)$$
M.5. f_{sw} model as a function of V_{eq} and I_{L} for a set Δi_{Lpp}:
$${\text{f}}_{\text{sw}} = {\text{f}}_{\text{fsw,} \text{Δ} \text{iLpp}} \left({\text{V}}_{\text{eq}} \text{,} {\text{I}}_{\text{L}} \text{,} {\text{c}}_{\text{fsw,1}} \left(\text{Δ} {\text{i}}_{\text{Lpp,ref}}\right) \text{,} {\text{c}}_{\text{fsw,2}} \left(\text{Δ} {\text{i}}_{\text{Lpp,ref}}\right) \text{,} …\right)$$
M.6. I_{L} model as a function of V_{eq} and f_{sw} for a set Δi_{Lpp}:
$${\text{I}}_{\text{L}} = {\text{f}}_{\text{IL,} \text{Δ} \text{iLpp}} \left({\text{V}}_{\text{eq}} \text{,} {\text{f}}_{\text{sw}} \text{,} {\text{c}}_{\text{IL,1}} \left(\text{Δ} {\text{i}}_{\text{Lpp,ref}}\right) \text{,} {\text{c}}_{\text{IL,2}} \left(\text{Δ} {\text{i}}_{\text{Lpp,ref}}\right) \text{,} …\right)$$
M.7. V_{eq} model as a function of f_{sw} and I_{L} for a set Tₛ:
$${\text{V}}_{\text{eq}} {\text{=f}}_{\text{Veq,Ts}} \left({\text{f}}_{\text{sw}} \text{,} {\text{I}}_{\text{L}} \text{,} {\text{c}}_{\text{Veq,1}} \left({\text{T}}_{\text{s,ref}}\right) \text{,} {\text{c}}_{\text{Veq,2}} \left({\text{T}}_{\text{s,ref}}\right) \text{,} …\right)$$
M.8. f_{sw} model as a function of V_{eq} and I_{L} for a set Tₛ:
$${\text{f}}_{\text{sw}} = {\text{f}}_{\text{fsw,Ts}} \left({\text{V}}_{\text{eq}} \text{,} {\text{I}}_{\text{L}} \text{,} {\text{c}}_{\text{fsw,1}} \left({\text{T}}_{\text{s,ref}}\right) \text{,} {\text{c}}_{\text{fsw,2}} \left({\text{T}}_{\text{s,ref}}\right) \text{,} …\right)$$
M.9. I_{L} model as a function of V_{eq} and f_{sw} for a set Tₛ:
$${\text{I}}_{\text{L}} = {\text{f}}_{\text{IL,Ts}} \left({\text{V}}_{\text{eq}} \text{,} {\text{f}}_{\text{sw}} \text{,} {\text{c}}_{\text{IL,1}} \left({\text{T}}_{\text{s,ref}}\right) \text{,} {\text{c}}_{\text{IL,2}} \left({\text{T}}_{\text{s,ref}}\right) \text{,} …\right)$$

The coefficients and independent variables identify the terminal nodes of the tree. The elementary functions identify the non-terminal nodes of the tree. The independent variables are the inputs to the model. The model output is the result of the sequence of operations defined by the elementary functions. Table 1 reports an exemplary, non-limiting list of possible elementary functions. A complexity index is associated with each elementary function, as indicated in Table 1 by way of a non-limiting example. The input variables are assigned a complexity index of 1. The complexity of the model is obtained as follows:
if a function is an argument of another function, then the complexity indices of the two functions are multiplied;
if two functions are multiplied or added, then their complexity indices are added and the result is subsequently multiplied by the complexity index of the product or sum, respectively;

Tabella 1. Elementary functions

| #inputs | Non-terminal | Description | Complexity |
|---|---|---|---|
| 2 | sum | ƒ + g | 1 |
| 2 | multiplication | ƒ · g | 1 |
| 2 | power | ƒ³ | 1.5 |
| 2 | division | ƒ/g | 1.5 |
| 1 | logarithm | log(ƒ) | 1.5 |
| 1 | natural exp. | exp(ƒ) | 1.5 |
| 1 | power | ƒ^{α} | 1.5 |
| 1 | exponential | α^{ƒ} | 1.5 |
| 1 | square root | $\sqrt{f}$ | 1.5 |
| 1 | hyperbolic tangent | tanh(ƒ) | 1.5 |
| 1 | inverse tangent | tan⁻¹(ƒ) | 1.5 |
| 1 | reciprocal | 1/ƒ | 1.5 |

The Genetic programming algorithm (J. R. Koza, Genetic Programming: On the Programming of Computers by Means of Natural Selection, MIT Press, Cambridge, 1992) which can be advantageously implemented in the method of the present invention, once the model to be generated (M.1, ..., M.9) has been determined, operates for example on a population of at least 100 models, optionally 500 models, which evolve over time over at least 100 generations, optionally 300 generations. Each model is a combination of elementary functions and coefficients, represented by a tree with a number of nodes not exceeding 100 nodes, optionally not exceeding 50 nodes. Starting from an initial population of models generated randomly, at each generation the precision with which each model reproduces the reference data is evaluated, and the population is then replaced by a new generation by applying a selection operator (in particular the binary tournament operator), of a cross-over operator (in particular the subtree cross-over operator) and of a mutation operator (in particular the subtre&note mutation operator), with equal cross-over probability of 80%, probability of subtree mutation equal to 18% and probability of node mutation equal to 2%.

The coefficients cₓ of the functions relating to the selected model can be determined, for the limit condition value {Δi_{Lpp,ref}, T_{s,ref}, P_{d,ref}}, for example through the Levenberg - Marquardt method, which identifies the best values of the coefficients, on the basis of the error minimization criterion χ² applied to the yₙ values of the dependent variable of the selected model obtained in the dataset of the independent variables on n samples of the independent variables (x_{1,i},x_{2,i}) i = 1, ..., n corresponding to the list of triplets obtained through the experimental tests. For example, in the case of model M.1 the error is expressed by the following formula:

$${X}^{2} = \frac{1}{n} {\sum }_{i = 1}^{n} {\left[{f}_{V e q , P d} \left({f}_{s w , i} , {I}_{L , i}\right) - {V}_{e q , i}\right]}^{2}$$

where V_{eq,i} is the experimental i-th value of the operative variable V_{eq} corresponding to the i-th experimental values ƒ_{sw,i} e l_{L,i} of the operational quantities ƒ_{sw} and l_{L}. The same formula applies to the remaining models M.2, ..., M.9.

It is evident that the advantage of models M.1, ..., M.9 consists in the fact that they allow putting into relation the operational parameters of an inductor in a direct and simpler way than traditional methods and verifying whether or not they meet certain response conditions. For example, in the case of model M.1, given V_{eq}, f_{sw} and l_{L}, and given the function f_{veq},_{pd(}f_{sw},iL) corresponding to a certain P_{d,ref}, graphically represented by surface 5, if V_{eq}<f_{veq,pd}(f_{sw},I_{L}) then P_{d}<P_{d,ref}. FIG. 11b shows some examples of functions generated by the algorithm above, based on model M.1, which describe in analytic form the locus of the operational parameters corresponding to surface 5 of FIG. 11a(a), that determine an inductor response that complies with the first limit condition, wherein in particular P_{d}=P_{d,ref}=200 mW;

The model obtained according to the method of the present invention (for example f_{Veq,Pd}(f_{sw},l_{L})) is defined on the samples of the surface it represents, for the identification of which few samples are sufficient, and which can be identified starting from the acquired experimental data limited to a neighbourhood thereof, in other words, without necessarily having to subject the inductor 2 to operational conditions which would determine a response very far from a limit operational condition of interest, of the type described above. It follows that, for the model obtained according to the method of the present invention, it is easier to obtain a good precision, since the model is valid on a portion restricted to a limited surface of the three-dimensional domain {[V_{eq,min}, V_{eq,max}],[f_{sw,min,} f_{sw,max}],[l_{L,min}, l_{L,max}]}.

The method 1 of the present invention can be advantageously implemented by a measuring station, indicated in FIGS. 12 to 17 with the reference 100, which is also the object of the present invention.

Such a measuring station 100, configured for the implementation of method 1 of the invention, includes:
one data control and processing unit 101, configured for defining the three-dimensional mathematical space 3, the exploration field 4, the working limit condition, the set R of response parameters, and configured for comparing the set R with said working limit condition;
a stimulus generation device 102, operatively connected to the data control and processing unit 101 and configured to generate at least one stimulus, comprising a time-varying voltage v_{L}(t) and a constant current l_{L}, as a function of the value of the coordinates (pₙ₁, pₙ₂, pₙ₃) of the point Pₙ selected in the explored three-dimensional mathematical space 3, and to apply the stimulus thus generated to inductor 2;
a detecting device 103, operationally connected to the data control and processing unit 101 and configured to detect a varying over time current i_{L}(t) across the inductor 2 as well as its surface temperature Tₛ, in response to the stimulus thus applied;
at least one storage unit 104, operatively connected to said data control and processing unit 101 and configured for storing the coordinates of the points P*ₙ of the three-dimensional mathematical space 3 wherein the working limit condition is met;
wherein the data control and processing unit 101 is configured to be connected to at least one remote processing unit 200 and to send the coordinates of such P*ₙ points thereby stored, to this remote processing unit 200.

The remote processing unit 200 can in turn be configured to apply at least one algorithm, optionally a Genetic Programming algorithm, to the finite set of such points P*ₙ received by the measuring station 100 and output a description in analytical form of the locus of such points P*ₙ, thus obtaining the locus 5 of the operational parameters which determine a response in the inductor 2 under investigation that complies with at least one working limit condition.

If desired, according to a preferred variant of the present invention, the data control and processing unit 101 can be physically distributed among several units, for example it can comprise a first data acquisition and control unit, optionally digital, indicated with the abbreviation UDAC in FIG. 12, and another data connection unit, indicated by the abbreviation UDCD in FIG. 12, also optionally digital, configured to connect the measuring station 100 according to the invention, for example to the remote processing unit 200 where it is physically performed the algorithm, optionally of Genetic Programming, which outputs the aforementioned description in analytical form of the locus of said stored P*n points.

According to a further variant of the measuring station 100 of the present invention, the data control and processing unit 101 can be configured to directly apply the above algorithm to the finite set of points stored in the storage 104, providing in output a description in analytical form of the locus of said points P*ₙ thus stored, and thus obtaining the locus 5 of the operational parameters which determine a response in the inductor 2 under investigation which comply with at least one working limit condition.

Not only that, the data control and processing unit 101 is configured to handle (through a firmware stored therein) steps A to C of method 1 of the present invention, namely:
the determination of the points Pₙ of the three-dimensional mathematical space 3 to be explored;
the actuation of device 102 for the generation and application of the stimulus to inductor 2, based on the determined points Pₙ;
the actuation of the detecting device 103, for detection of the varying over time current i_{L}(t) of the inductor; and
the calculation of all the parameters required for the implementation of such method.

According to a preferred embodiment of the measuring station 100 of the present invention, the stimulus generation device 102 is advantageously obtained through three power converting stages operatively connected in cascade according to the so-called Opposition Method (for example as taught in F. Forest et al., “Use of opposition method in the test of high-power electronic converters,” in IEEE Transactions on Industrial Electronics, vol. 53, no. 2, pp. 530-541, April 2006), in order to subject inductor 2 under investigation to a stimulus corresponding to a triplet of the operational conditions described above.

The stimulus, as already mentioned in the introduction, comprises a zero mean square wave voltage, typical of hard-switching dc-dc PWM power converters, and a direct current, the characteristics of which, according to the present invention, are set by means of such converter stages.

More particularly, the three power converter stages comprise an Input Stage Sdl, a Test Stage SdT and an Output Stage SdU, wherein the Test Stage SdT is connected between the Input Stage Sdl and the Output stage SdU and is further configured to be connected to the inductor 2 to be investigated.

The Output Stage SdU is configured to operate in a closed loop and impose a direct current at the output of the Test Stage SdT, by adjusting its own average input current Iₒ: the SdU, therefore, operates as a variable direct current electrical load for SdT. The output of the Output Stage SdU is therefore connected to the input of the Test Stage SdT, so that the output current of SdU is returned to the input of SdT, so as not to make it strictly necessary, but optional, the inclusion of a power dissipating element (load EL in FIG. 12), required to absorb the power that the SDT must deliver at the operational conditions to which the inductor 2 is subjected. In practice, this translates into a significant reduction in the power required for the operation of the measuring station.

As can be seen from FIG. 12, therefore, according to a variant of the measuring station 100 of the invention, downstream of the Output Stage SdU, a switching element (Single Pole Double Throw or SPDT) of the output current can be provided, towards the SdT input or towards the external load EL, to allow in the latter case the measuring station 100 to operate even at different conditions, not foreseen in the case in which the Test Stage SdT is connected in a closed loop with the Output Stage.

The Input Stage Sdl is configured to work in closed loop and provide in input to the Test Stage SdT one direct voltage, through adjustment of its output voltage Vᵢ, and the Test stage SdT is configured to work in open loop and provide for the switching frequency of the varying over time zero mean square wave voltage v_{L}(t), through adjustment of its own frequency fₜ and duty cycle Dₜ. In other words, the Test Stage modulates the direct voltage which is imposed by the Input Stage Sdl with the direct current l_{L} which is imposed on it by the Output stage SdU and therefore imposes to the terminals of the inductor 2 connected thereto the stimulus above described, comprising a varying over time square wave voltage v_{L}(t) as described above and a direct current l_{L}.

The above adjustments are made based on specific control signals emitted by the data control and processing unit 101, according to a temporal sequence determined by an algorithm (firmware) which is stored in the data control and processing unit 101 or is supplied to it, by means of another processing unit, even a remote one (for example 200 in FIG. 12). For example, as will also be seen below, the data control and processing unit 101, which can be optionally based on a micro controller, is configured to supply digital signals PWMi1, PWM2, PWMt and PWMu to stages Sdl, SdT and SdU, based on analog reference values V_{i,ref} e l_{o,ref}, f_{t,ref} and D_{t,ref},, received from the outside or from storage unit 104 and correlated to the coordinates of points P*ₙ previously stored therein, or from remote unit SI.

The detecting device 103 of the measuring station 100, according to a preferred variant of the invention represented in FIG. 12, is integrated in the stimulus generation device 102 and is therefore also advantageously obtained through the Input Stage Sdl, Test Stage SdT and Output Stage SdU. The detecting device 103 comprises respective sensors, configured to supply the actually measured signal of the input current I_{o,mis} of the SdU (corresponding to the mean value l_{L,av} of current i_{L}(t) represented in FIG. 1, for method 1) to the data control and processing unit 101 (more particularly to its acquisition and control unit UDAC).

Not only that, those sensors are configured to send to the data control and processing unit 101 also a measured signal of the output voltage V_{i,mis} of Sdl (which is one of the elements that help define the voltage v_{L}(t) of method 1 - in particular the component V_{Lr} of v_{L}(t) corresponds to the difference between Vi (output voltage of the Sdl) and Vo (output voltage of SdT), while V_{Lf} of v_{L}(t) corresponds to the opposite of Vo (reference is always made to FIG. 12) and of the frequency f_{t,mis}, duty cycle D_{t,mis}, peak-to-peak current D_{iLppt,mis} and surface temperature T_{s,mis} of the inductor 2 connected to the Test Stage SdT.

Those signals are produced by the analog conditioning circuits incorporated in the three stages Sdl, SdT and SdU.

In this regard, the attached FIGS. 13 to 15 show preferred embodiments, given for illustrative and non-limiting purposes, of circuit implementations of the aforementioned three stages Sdl, SdT and SdU.

As can be seen (FIG. 13), the Input Stage Sdl can be implemented by means of a noninverting step-up-down (buck-boost) DC-DC converter with four synchronous rectification switches. The Sdl can use two distinct signals, PWMi1 and PWMi2, to control step-up and step-down operation, respectively. According to a preferred embodiment of the invention, during step-down operation, PWMi1 signal is active, the duty cycle Di1 of which being adjustable through a firmware implementing a first Digital Linear Controller (CLDi1), while PWMi2 signal is set to 0. Vice versa, during step-up operation, PWMi2 signal is active, the duty cycle Di2 of which being adjustable through a firmware that implements a second Digital Linear Controller (CLDi2), while PWMi1 signal is set to 1.

The Test Stage (FIG. 14) can be implemented through a step-down (buck) DC-DC converter with synchronous rectification. According to a preferred embodiment of the measuring station 100 of the present invention, the Test stage comprises (see, in particular, FIGS. 16 and 17):
a printed circuit 105 having conductive tracks 106, configured to provide the inductor 2 with the varying over time voltage v_{L}(t) and the direct current l_{L}, wherein the conductive tracks 106 have at least one surface portion 1061, configured to enter electrically into contact with inductor 2; and
a system 107 for positioning the inductor 2 on the printed circuit 105, wherein the inductor 2 is in electrical contact with the conductive tracks 106 of the printed circuit 105, without the need for welding.

In the measuring station 100 of the invention, the positioning system 107 comprises:
one positioning plate 1071; and
one group 1072 for the elastic anchoring of said positioning plate 1071 to said printed circuit 105.

The elastic anchoring group 1072 comprises one couple of elastically charged screws 10721, configured for being screwed on said printed circuit 105, passing through suitable openings obtained in said positioning plates 1071.

In this way, the inductor 2 is configured to be placed between the printed circuit 105 and the positioning plate 1071 and to be subjected to a pressure towards the conductive tracks 106 of the printed circuit 105, by means of the elastic anchoring group 1072 thus realizing with them an electrical contact.

On the positioning plate 1071 one of the aforementioned sensors (not shown in the drawings) is also provided, configured to detect and transmit the surface temperature T_{s,mis} of the inductor 2 under investigation to the data control and processing unit 101.

As can be seen from the attached figures, the surface portion 1061 of the conductive tracks 106 has a polygonal configuration, optionally a trapezoidal one, which allows electrically and easily connecting inductors 2 of various sizes to the conductive tracks 106 of the measuring station 100, without the need for welding.

The advantages of this architecture, for the measuring station 100 of the present invention, are many. First of all, it does not require a dissipative load at the output of the SdU output stage and this therefore allows its dimensions to be reduced to a minimum. It also reduces the power that the Input Stage must deliver, equal to the sum of the losses of the SdT and SdU and allows the use of a low power AC / DC mains power supply (see FIG. 12), for example a standard rectifier, which must in fact deliver a power equal to the sum of the losses of the three SdI, SdT and SdU stages.

Again, purely by way of non-limiting example, the aforementioned Input Stage Sdl can be designed in such a way as to have:

input voltage 24 V DC or 220 Vrms AC;
continuous output voltage adjusted to a value between 12 V and 48 V;
maximum output current 10 A;
efficiency at maximum current not less than 90%;
overcurrent, overvoltage, open circuit, and short circuit protections;
circuitry for measuring the value of the output voltage with a minimum precision of 1%.

The Test Stage SdT can be designed to have:
input voltage between 12 V and 48 V;
output voltage between 6 V and 42 V;
maximum output current 10 A;
maximum peak current of the inductor 20 A;
duty-cycle comprised between 10% and 90%;
switching frequency comprised between 100 kHz and 1 MHz;
efficiency at maximum current not less than 90%;
overcurrent, overvoltage, open circuit, and short circuit protections;
inductor connection system with no welding, with contacts at a distance between 2 mm and 2 cm and contact resistances not exceeding 10 mΩ;
circuitry for measuring the peak-to-peak current of the inductor with a minimum precision of 2%;
circuitry for measuring the surface temperature of the inductor with a minimum precision of 1° C.;
circuitry for measuring the switching frequency with a minimum precision of 1%;
circuitry for measuring the duty-cycle with a minimum precision of 1%.

The Output Stage SdU can be designed to have:
input voltage between 6 V and 42 V;
output voltage ≤ 48 V;
Adjustable input current between 0 and 10 A;
maximum input current 10 A;
efficiency at maximum current not less than 90%;
overcurrent, overvoltage, open circuit, and short circuit protections;
circuitry for measuring the mean input current with a minimum precision of 1%.

The measuring station 100 described above, according to a variant of the invention and as anticipated above, can be used in conjunction with a remote processing unit 200, in a system 1000 for the implementation of method 1 of the present invention.

In system 1000, some embodiments of which are represented purely by way of non-limiting example in FIGS. 11 to 13, the measuring station 100 and the remote processing unit 200 can be operationally connected through a data network, optionally via cable or wirelessly.

Such system 1000 is configured for carrying out the method 1 of the present invention on the power inductors 2 which operate in typical conditions of hard-switching dc-dc PWM power converters, according to a suitable sequence of operational parameters given by the invention method 1. System 1000, according to a preferred embodiment of the invention, comprises:
one or more Measuring Stations (SM) 100, independent from one another;
one or more remote processing unit (PC) 200; and
one interfacing system (SI) for example via software, between the two.

The architecture of system 1000 of the present invention is conceived as an open laboratory, which can be used by a single user or by a community of users and managed by an administrator. For this purpose, the software architecture can envisage three distinct types of remote processing units 200: one that operates as a System Administration (IAS), one that manages the actual execution of the measurement tests (AGE - the algorithm for determining the locus of the points of the three-dimensional mathematical space 3 that comply with the limit condition is physically executed on this unit) and a System Brokerage or Routing Unit (UBS), as illustrated in FIG. 18.

According to a preferred embodiment of the invention, two operational modes are provided in system 1000:
Autonomous: the measuring station 100 autonomously carries out the experimental tests. In this mode, before starting the tests, it will be necessary to send the measuring station 100 one file comprising a sequence to be used (optionally stored in the storage unit 104) for the generation of the stimuli and the relative parameters as well as the predetermined operational threshold conditions, etc. During the test session, the measuring station 100 will send the sampled data to the remote processing unit 200 with a frequency that can be programmed in the configuration step. It will be possible to interrupt the test session at any time, to change the algorithm and parameters sent, for example, by a user via the remote processing unit 200, and then restart the session with the newly set configuration.
Centralized: the test session is completely managed by the remote processing unit 200. In this mode, the measuring station 100 just executes the commands sent by the remote processing unit 200 and transmits the results thereto, which are sampled at a frequency that is preprogrammed in the configuration step.

According to a further variant of the system 1000 of the present invention, this can work according to a:
Stand Alone modality: in this modality the network of measuring stations 100 does not provide connection points with the outside and it is not necessary to have a network infrastructure in the operational environments (FIG. 19).
Connected modality: in this mode the system 1000 is connected to a network and the remote processing units 200 communicate with the system 1000 through this network. In the case wherein an internet connection is available at the operational site, the management and control of the system 1000 can be carried out also by using remote locations (FIG. 20).

In view of the aforementioned description and the examples provided, the advantages offered by the method 1, the measuring station 100 and system 1000 of the present invention are clear.

In fact, thanks to method 1, the measuring station 100 and the system 1000 described above, it is possible to determine, quickly, with less computational effort than traditional methods, in a safe and reliable way, a function that describes in analytical form the locus 5 of the operational parameters (points P*ₙ) of an electrical or electronic power component that respect the working limit condition, for example a value of the peak-to-peak current ripple Δi_{Lpp}=Δi_{Lpp,ref}, and/or its surface temperature Tₛ=T_{s,ref}, and/or its dissipated power P_{d}=P_{d,ref}.

The locus 5 of those operational parameters can be used by an operator, through the measuring station 100 or the system 1000 described above, to determine (for example visually by means of a display which can be operatively connected to such measuring station 100 or to a component of such system 1000) if starting from a triplet of operational parameters of the inductor under investigation, such inductor 2 complies or not with a limit condition. For example, according to a variant of the present invention, one or more mobile devices can be connected to the measuring station or system 1000, for example through the wifi, for displaying the results obtained by the method described above.

In the foregoing the preferred embodiments were described, and some modifications of the present invention were suggested, but it should be understood that those skilled in the art can make modifications and changes without departing from the relative scope of protection, as defined by the appended claims.

Thus, for example, as anticipated in the introduction, it is specified that although the present invention has been described with particular reference to power inductors, it is quite clear that it can also be applied to other electronic power components such as power capacitors, taking into account that where in this text reference is made to the voltage one should instead refer to the current and vice versa, and that where in this text reference is made to the inductance L one should instead refer to the capacitance C. In this case, the stimulus applied to the capacitor during step C.2 of method 1 would comprise a given square wave current i_{c}(t), varying over time, and an average voltage V_{C,av} and the response measured at step C.3 would comprise a varying over time voltage v_{c}(t), detected at the terminals of the same capacitor. Similarly, based on the measured response, corresponding response parameters at step C.4 would be determined comprised between the voltage ripple Δv_{Cpp}, the surface temperature Tₛ of the capacitor, and the average electrical power P_{d} dissipated by the capacitor.

1. A method for determining the behaviour of one electrical or electronic power component, with respect to a working limit condition, the method comprising the following operational steps:
A. defining one three-dimensional mathematical space of operational parameters of interest for said electrical or electronic power component, wherein the coordinates of an n-th point Pₙ of said three-dimensional mathematical space correspond to specific values of said operational parameters of interest for said electrical or electronic power component;
B. defining one exploration field of said three-dimensional mathematical space, the working limit condition for said electrical or electronic power component and one set R of response parameters of interest for said electrical or electronic power component;
C. exploring, said three-dimensional mathematical space by:
generating at least one stimulus, determined based on the coordinates of the points Pₙ of said three-dimensional mathematical space and on said exploration field,
applying said at least one stimulus to said at least one electrical or electronic power component, and
detecting one corresponding response to said stimulus thereby applied, from said electrical or electronic power component, and
based on said response thereby detected, determining, and storing one finite subset of points P*ₙ of said three-dimensional mathematical space, among the points Pₙ of said three-dimensional mathematical space, for which said working limit condition of said electronic power component is met; and
D. determining one mathematical model that analytically describes the locus of said points P*ₙ of said three-dimensional mathematical space thereby stored, thus obtaining the locus of said operational parameters that determine a response of said electrical or electronic power component that meets said working limit condition.

2. The method according to claim 1, wherein said operational parameters of interest for said electrical or electronic power component are selected among:
one equivalent voltage V_{eq} to be applied to said electrical or electronic power component;
one switching frequency f_{sw} for one entire charge-discharge cycle of said electrical or electronic power component;
one average current I_{L} flowing thorough said electrical or electronic power component; and
one temperature Tₐ of the environment wherein said electrical or electronic power component is operational.

3. The method according to claim 1, wherein said three-dimensional mathematical space is defined by assigning to each one of said operational parameters of interest of said electrical or electronic power component, one corresponding mathematical axis of a Euclidean three-dimensional mathematical space.

4. The method according to claim 1, wherein said at least one exploration field is defined by selecting:
one finite subset of points Pₙ of said three-dimensional mathematical space; and
one ordered set of three directions of exploration of the points of said exploration field, starting from any point Pₙ₋₁ to a next point Pₙ.

5. The method according to claim 4, wherein the exploration of said three-dimensional mathematical space is carried out, starting from one starting point Pₙ of said exploration field, along said directions of exploration, in an orderly way, and according to one exploration rule such that the coordinates of an explored n-th point Pₙ of said three-dimensional mathematical space differ from those of a previous point Pₙ₋₁, for the value of one or more of its components.

6. The method according to claim 4, wherein the coordinates (pₙ₁, pₙ₂, pₙ₃) of points Pₙ of said exploration field have values comprised between one minimum value and one maximum value of respective operational parameters (V_{eq}, f_{sw}, I_{L}) and wherein the finite number of said points Pₙ of said exploration field is a function, for each one of said directions of exploration of said three-dimensional mathematical space, of:
one number of samples (NV_{eq}, Nf_{sw}, NI_{L}); and
one offset (ΔV_{eq}, Δf_{sw}, ΔI_{L}) between one sample and the next one along the respective direction of exploration.

7. The method according to claim 6, wherein for each direction of said directions of exploration:
said number of samples (NV_{eq}, Nf_{sw}, NI_{L}) is fixed, and said offset (ΔV_{eq}, Δf_{sw}, ΔI_{L}) is fixed and constant; or
said number of samples (NV_{eq}, Nf_{sw}, NI_{L}) is fixed, and said offset (ΔV_{eq,i}, Δf_{sw,j}, ΔI_{L,k}) varies between two subsequent samples; or
said number of samples (NV_{eq}, Nf_{sw}, NI_{L}) depends on one offset (ΔV_{eq,i}, Δf_{sw,j}, ΔI_{L,k}) that is calculated, during said exploration of said exploration field, for each point Pₙ, .

8. The method according to claim 1, wherein the compliance or not of said working limit condition in any point Pₙ of said three-dimensional mathematical space depends on the value of at least one response parameter of said set R of response parameters of said electrical or electronic power component, the response parameters being determined based on the response detected from said electrical or electronic power component, after the application of said stimulus to its terminals, and on a pre-set search logic.

9. The method according to claim 8, wherein said response parameter of said set R of response parameters of said electrical or electronic power component is one among:
one peak-to-peak variation Δi_{Lpp} of a current i_{L}(t) that varies over time and flows through said electrical or electronic power component;
one surface temperature Tₛ of said electrical or electronic power component;
one average electrical power P_{d} dissipated by said electrical or electronic power component.

10. The method according to claim 8, wherein said working limit condition of said electrical or electronic power component is a function of a prefixed threshold value (Δi_{Lpp,ref}, T_{s,ref}, P_{d,ref}) for each response parameter.

11. The method according to claim 10, wherein said at least one response parameter is compliant with said at least one working limit condition if its value is lower than or equal to a respective threshold value (Δi_{Lpp,ref}, T_{s,ref}, P_{d,ref}).

12. The method according to claim 1, wherein said step C comprises:
C.1 selecting, through a data control and processing unit, one starting point Pₙ comprised in said exploration field and one first direction of exploration of said exploration field;
C.2 generating, through one stimulus generating device, one stimulus comprising one varying over time voltage v_{L}(t) and one constant average current I_{L}, based on the value of the coordinates of said point Pₙ just selected, and applying said stimulus thereby generated to the terminals of said electrical or electronic power component;
C.3 detecting at the terminals of said electrical or electronic power component, through one detecting device, in reply to said stimulus thereby applied, at least one corresponding current i_{L}(t) which varies over time and flows through said electrical or electronic power component, and one corresponding surface temperature Tₛ;
C.4 determining, through said data control and processing unit, said set R of response parameters, based on said current i_{L}(t) and said surface temperature Tₛ thereby detected; and
C.5 comparing, through said data control and processing unit, each element of said set R of response parameters with said working limit condition; and
C.6 if said working limit condition is met at said point Pₙ:
C.6.1 selecting a new point Pₙ of said three-dimensional mathematical space, along said first selected direction of exploration; and
C.6.2 if said point Pₙ is comprised within said exploration field, going back to step C.2;
otherwise going to step C.8
C.7 if said working limit condition is not met at said point Pₙ:
C.7.1if said point Pₙ just selected is the starting point of said exploration field:
C.7.1.1 selecting a new point Pₙ of said three-dimensional mathematical space, along said first selected direction of exploration; and
C.7.1.2 if said new point Pₙ is comprised within said exploration field:
C.7.1.2.1 carrying out steps C.2-C.5 and
C.7.1.2.2 if said working limit condition is not met in said new point Pₙ, going back to step C.7.1.1,
otherwise, going back to step C.6;
otherwise going to step C.8
otherwise C.7.2 if said point Pₙ just selected and the point Pₙ₋₁ previous to that are located along said first direction of exploration:
C.7.2.1 determining, through said data control and processing unit, and storing, in a storage unit, the coordinates (p*ₙ₁, p*ₙ₂, p*ₙ₃) of another point P*ₙ of the three-dimensional space 3, that is comprised in the neighbourhood of said point Pₙ of said exploration field, along said first selected direction of exploration, wherein said working limit condition is met;
C.7.2.2 selecting the point Pₙ₋₁ previous to said Pₙ and, starting from that, a new point Pₙ, along the second direction of exploration; and
C.7.2.3 if said newly selected point Pₙ is comprised within said exploration field, going back to step C.2;
otherwise going to step C.8
otherwise C.7.3 if said point Pₙ just selected and the point Pₙ₋₁ previous to that are placed along the second direction of exploration:
C.7.3.1 selecting a new point Pₙ of the three-dimensional mathematical space, along the first selected direction of exploration; and
C.7.3.2 if said newly selected point Pₙ is comprised within said exploration field, going back to step C.2; otherwise going to step C.8
C.8 if said point Pₙ just selected is not comprised within said exploration field:
C.8.1 selecting, along said second direction of exploration, a new point Pₙ of the three-dimensional mathematical space, starting from the previously selected point Pₙ₋₁ and, if the newly selected point Pₙ is comprised within said exploration field, going back to step C.2; otherwise
C.8.2 selecting, along said third direction of exploration, a new point Pₙ of the three-dimensional mathematical space, starting from the previously selected point Pₙ₋₁ and, if the newly selected point Pₙ is comprised within said exploration field, going back to step C.2; otherwise going to said step D of said method.

13. The method according to claim 12, wherein the stored coordinates of said point P*ₙ of said mathematical space, which point is comprised in the neighbourhood of said point Pₙ of said exploration field, are calculated through an interpolation formula.

14. The method according to claim 1, wherein said step D comprises applying to said points P*ₙ of said mathematical space thereby stored, through said data control and processing unit, at least one Genetic Programming or Grammatical Evolution algorithm.

15. A measuring station, configured for implementing a method for determining the behaviour of an electrical or electronic power component with respect to a working limit condition, the method comprising the following operational steps:
A. defining one three-dimensional mathematical space of operational parameters of interest for said electrical or electronic power component, wherein the coordinates of an n-th point Pₙ of said three-dimensional mathematical space correspond to specific values of said operational parameters of interest for said electrical or electronic power component;
B. defining one exploration field of said three-dimensional mathematical space, the working limit condition for said electrical or electronic power component and one set R of response parameters of interest for said electrical or electronic power component;
C. exploring, said three-dimensional mathematical space by:
generating at least one stimulus, determined based on the coordinates of the points Pₙ of said three-dimensional mathematical space and on said exploration field,
applying said at least one stimulus to said at least one electrical or electronic power component, and
detecting one corresponding response to said stimulus thereby applied, from said electrical or electronic power component, and
based on said response thereby detected, determining, and storing one finite subset of points P*ₙ of said three-dimensional mathematical space, among the points Pₙ of said three-dimensional mathematical space, for which said working limit condition of said electronic power component is met; and
D. determining one mathematical model that analytically describes the locus of said points P*ₙ of said three-dimensional mathematical space thereby stored, thus obtaining the locus of said operational parameters that determine a response of said electrical or electronic power component that meets said working limit condition.
said measuring station comprising:
one data control and processing unit, configured for defining said three-dimensional mathematical space, said exploration field, said working limit condition, said set R of response parameters, and for comparing each element of said set R, determined for the explored points of said three-dimensional mathematical space, with said working limit condition;
one stimulus generating device, operatively connected to said data control and processing unit and configured for generating at least one stimulus, the stimulus comprising at least one zero mean and square wave voltage v_{L}(t) and one constant average current I_{L} for said electrical or electronic power component, based on the value of the coordinates of said point Pₙ of said three-dimensional mathematical space (3), said coordinates being associated to respective values of said operational parameters (V_{eq}, fs_{w}, I_{L}) of said electrical or electronic power component, and for applying said stimulus thereby generated to said electrical or electronic power component;
one detecting device, operatively connected to said data control and processing unit and configured for detecting said at least one varying over time current i_{L}(t) and one surface temperature Tₛ of said electrical or electronic power component, in reply to said stimulus thereby applied;
at least one storage unit, operatively connected to said data control and processing unit and configured for storing the coordinates of the points P*ₙ of said mathematical space wherein said working limit condition is met;
wherein said data control and processing unit is configured for applying to said coordinates of said points P*ₙ thereby stored, at least one mathematical algorithm, said at least one mathematical algorithm providing for in output a description, in analytical form, of the locus of said points P*ₙ, and thus the locus of the corresponding operational parameters that determine a response from said electrical or electronic power component that meets said at least one working limit condition.

16. The measuring station according to claim 15, wherein said one stimulus generating device and said detecting device are obtained through three power converter stages operatively connected in cascade according to an Opposition Method, so as to:
subject said at least one electrical or electronic power component to said at least one stimulus, based on the value of the coordinates of said point Pₙ; and
detect at least one varying over time current i_{L}(t) and one surface temperature Tₛ of said electrical or electronic power component.

17. The measuring station according to claim 15, wherein said three converters comprise an Input Stage SdI, a Test Stage SdT and an Output Stage SdU, wherein the Test Stage SdT is connected between the Input Stage SdI and the Output stage (SdT) and is further configured to be connected to said electrical or electronic power component.

18. The measuring station according to claim 17, comprising downstream of said Output Stage SdU one switching element (SPDT) of the current output from said Output Stage SdU, toward the input of the Test Stage SdT or an external load (EL).

19. The measuring station according to claim 17, wherein said Input Stage SdI is configured to work in closed loop and provide in input to said Test Stage SdT one direct voltage, through adjustment of the output voltage Vᵢ thereof, and said Test stage SdT is configured to work in open loop and provide for a switching frequency of said zero mean and square wave voltage v_{L}(t), through adjustment of its own frequency fₜ and duty cycle Dₜ.

20. The measuring station according to claim 17, wherein said Output stage SdU is configured to operate in closed loop and impose at the output of said Test Stage SdT a direct current, through adjustment of its own input average current.

21. The measuring station according to claim 15, comprising:
one printed circuit having conductive paths, configured for imposing said stimulus to said electrical or electronic power component, wherein said conductive paths have at least one surface portion configured for electrically entering into contact with said electrical or electronic power component; and
one positioning system for said electrical or electronic power component on said printed circuit, wherein said electrical or electronic power component is in electrical contact with said conductive paths of said printed circuit, without need for welds.

22. The measuring station according to claim 21, wherein said positioning system comprises:
one positioning plate; and
one group for the elastic anchoring of said positioning plate to said printed circuit;
said electrical or electronic power component being configured for being placed between said printed circuit and said positioning plate and being subjected to one pressure toward said conductive paths of said printed circuit, through said elastic anchoring group.

23. The measuring station according to claim 22, wherein said elastic anchoring group comprises one couple of elastically charged screws, configured for being screwed on said printed circuit, passing through suitable openings obtained in said positioning plates.

24. The measuring station according to claim 21, wherein said conductive paths have a polygonal, configuration.

25. The measuring station according to claim 21, wherein said detecting device comprises at least one temperature sensor, operatively connected to said data control and processing unit and configured for detecting said surface temperature Tₛ of said electrical or electronic power component and for transmitting it to said data control and processing unit.

26. A system for implementing a method for determining the behaviour of an electrical or electronic power component to with respect to a working limit condition, the method comprising the following operational steps:
A. defining one three-dimensional mathematical space of operational parameters of interest for said electrical or electronic power component, wherein the coordinates of an n-th point Pₙ of said three-dimensional mathematical space correspond to specific values of said operational parameters of interest for said electrical or electronic power component;
B. defining one exploration field of said three-dimensional mathematical space, the working limit condition for said electrical or electronic power component and one set R of response parameters of interest for said electrical or electronic power component;
C. exploring, said three-dimensional mathematical space by:
generating at least one stimulus, determined based on the coordinates of the points Pₙ of said three-dimensional mathematical space and on said exploration field,
applying said at least one stimulus to said at least one electrical or electronic power component, and
detecting one corresponding response to said stimulus thereby applied, from said electrical or electronic power component, and
based on said response thereby detected, determining, and storing one finite subset of points P*ₙ of said three-dimensional mathematical space, among the points Pₙ of said three-dimensional mathematical space, for which said working limit condition of said electronic power component is met; and
D. determining one mathematical model that analytically describes the locus of said points P*ₙ of said three-dimensional mathematical space thereby stored, thus obtaining the locus of said operational parameters that determine a response of said electrical or electronic power component that meets said working limit condition.
said system comprising at least one measuring station including:
one data control and processing unit configured for defining said three-dimensional mathematical space, said exploration field, said working limit condition, said set R of response parameters, and for comparing each element of said set R, determined for the explored points of said three-dimensional mathematical space, with said working limit condition;
one stimulus generating device, operatively connected to said data control and processing unit and configured for generating at least one stimulus, the stimulus comprising at least one zero mean and square wave voltage v_{L}(t) and one constant average current I_{L} for said electrical or electronic power component, based on the value of the coordinates of said point Pₙ of said three-dimensional mathematical space (3), said coordinates being associated to respective values of said operational parameters (V_{eq}, fs_{w}, I_{L}) of said electrical or electronic power component, and for applying said stimulus thereby generated to said electrical or electronic power component;
one detecting device, operatively connected to said data control and processing unit and configured for detecting said at least one varying over time current i_{L}(t) and one surface temperature Tₛ of said electrical or electronic power component, in reply to said stimulus thereby applied;
at least one storage unit, operatively connected to said data control and processing unit and configured for storing the coordinates of the points P*ₙ of said mathematical space wherein said working limit condition is met;
wherein said data control and processing unit is configured for applying to said coordinates of said points P*ₙ thereby stored, at least one mathematical algorithm, said at least one mathematical algorithm providing for in output a description, in analytical form, of the locus of said points P*ₙ, and thus the locus of the corresponding operational parameters that determine a response from said electrical or electronic power component that meets said at least one working limit condition, and at least one remote processing unit, wherein said measuring station and said remote processing unit are operatively connected to each other, and wherein said data control and processing unit of said measuring station is configured to send to said at least one remote processing unit said coordinates of said points P*ₙ thereby stored, and said at least one remote processing unit is configured to apply at least one mathematical algorithm, providing for in output a description, in analytical form, of the locus of said points P*ₙ, and therefore the locus of the corresponding operational parameters that determine a response from said electrical or electronic power component that meets at least one working limit condition.

27. The method according to claim 4, wherein each direction of exploration is parallel to a respective axis of said three-dimensional mathematical space.

28. The method according to claim 7, wherein:
when said number of samples (NV_{eq}, Nf_{sw}, NI_{L}) is fixed, said offset (ΔV_{eq,i}, Δf_{sw,j}, ΔI_{L,k}) varies between two subsequent samples according to one function selectable between a pre-set logarithmic, power, trigonometric, transcendent, or numerical series function; or
when said number of samples (NV_{eq}, Nf_{sw}, NI_{L}) depends on one offset (ΔV_{eq,i}, Δf_{sw,j}, ΔI_{L,k}) that is calculated, during said exploration of said exploration field, for each point Pₙ, said offset (ΔV_{eq,i}, Δf_{sw,j}, ΔI_{L,k}) is calculated based on one value of one set R of response parameters, which response parameters are calculated at the last two points Pₙ₋₁ e Pₙ₋₂ explored in said exploration field.

29. The method according to claim 13, wherein said interpolation formula is linear.

30. The measuring station according to claim 15, wherein said mathematical algorithm is a Genetic Programming or Grammatical Evolution algorithm.

31. The system according to claim 26, wherein said mathematical algorithm is a Genetic Programming or Grammatical Evolution algorithm.
